(19) United States
(12) Patent Application Publication
(10) Pub. No.: US 2017/0033119 A1
(43) Pub. Date: Feb. 2, 2017

(54) Vertical Non-Volatile Semiconductor Devices

(71) Applicants: Kwang Chul Park, Suwon-si (KR); Jang Gn YUN, Hwaseong-si (KR); Won Bong JUNG, Seoul (KR)

(72) Inventors: Kwang Chul Park, Suwon-si (KR); Jang Gn YUN, Hwaseong-si (KR); Won Bong JUNG, Seoul (KR)

(21) Appl. No.: 15/165,123

(22) Filed: May 26, 2016

(30) Foreign Application Priority Data
Jul. 28, 2015 (KR) 10-2015-0106401

(51) Int. Cl. H01L 27/115

(52) U.S. Cl. CPC H01L 27/11582; H01L 27/1157; H01L 27/11565

(57) ABSTRACT

Semiconductor device are provided including a stacked structure having gate electrodes and interlayer insulating layers alternately stacked on a substrate; channel holes extending perpendicular to the substrate through the stacked structure and including channel regions therein; and horizontal parts at lower portions of the stacked structure and including areas in which the channel regions are horizontally elongated from the channel holes. The horizontal parts surround respective channel holes and are connected to each other between at a least portion of the channel holes.

### CROSS-REFERENCE TO RELATED APPLICATION

This application claims priority to and the benefit of Korean Patent Application No. 10-2015-0106401, filed on Jul. 28, 2015 with the Korean Intellectual Property Office, the content of which is hereby incorporated herein by reference as if set forth in its entirety.

### FIELD

The present inventive concept relates generally to semiconductor devices and, more particularly, to vertical non-volatile semiconductor devices.

### BACKGROUND

Semiconductor devices have gradually been reduced in size while simultaneously being required to be able to process massive amounts of data. Accordingly, a degree of integration of semiconductor devices used in such semiconductor apparatuses has increased. To increase the degree of integration of such semiconductor devices, semiconductor devices having a vertical transistor structure instead of the existing planar transistor structure have been proposed.

### SUMMARY

Some embodiments of the present inventive concept provide a semiconductor device including a stacked structure having gate electrodes and interlayer insulating layers alternately stacked on a substrate; channel holes extending perpendicular to the substrate through the stacked structure and including channel regions therein; and horizontal parts at lower portions of the stacked structure and including areas in which the channel regions are elongated perpendicularly from the channel holes. The horizontal parts surround respective channel holes and are connected to each other between at least a portion of the channel holes.

In further embodiments, the horizontal parts may be connected to each other between respective channel holes parallel in one direction among the channel holes.

In still further embodiments, the horizontal parts may include circular portions surrounding respective channel holes, and at least a portion of the circular portions may be connected to each other.

In some embodiments, the semiconductor device may further include a horizontal filling layer alongside the horizontal parts and filling a space between the horizontal parts.

In further embodiments, the horizontal filling layer may include an isolated portion surrounded by the horizontal parts.

In still further embodiments, the semiconductor device may further include gate dielectric layers extending perpendicular to the substrate along the channel regions and between the channel regions and the gate electrodes. The horizontal parts may include portions formed by horizontally elongated gate dielectric layers.

In some embodiments, in the horizontal parts, the gate dielectric layers may be on upper and lower surfaces of the channel regions and do not cover side surfaces of the channel regions.

In further embodiments, the lower surfaces of the channel regions may be isolated from the substrate by the gate dielectric layers.

In still further embodiments, the horizontal parts may include at least two layers spaced apart from each other in a direction perpendicular to the upper surface of the substrate.

In some embodiments, the semiconductor device may further include a lower interlayer insulating layer between the horizontal parts and the substrate.

In further embodiments, the channel holes may extend through the horizontal parts and recess portions of the substrate.

In still further embodiments, the semiconductor device may further include contact lines between the channel holes at predetermined intervals and connected to at least one of the horizontal parts and the substrate.

In some embodiments, the contact lines may be electrically connected to the horizontal parts.

In further embodiments, the contact lines may include a vertically arranged first impurity area and a second impurity area, each respectively including different conductivity-type impurities.

Still further embodiments of the present inventive concept provides a semiconductor device including a stacked structure having gate electrodes and interlayer insulating layers alternately stacked on a substrate; channel holes extending perpendicular to the substrate through the stacked structure; horizontal parts between the substrate and the stacked structure, surrounding respective channel holes and connected to each other between at least a portion of the channel holes, and a horizontal filling layer disposed alongside the horizontal parts and filling a space between the horizontal parts.

Some embodiments of the present inventive concept provide semiconductor devices including a semiconductor substrate; a stacked structure including gate electrodes on the semiconductor substrate; a supporting structure between the semiconductor substrate and the stacked structure; and channel holes extending perpendicular to the semiconductor substrate and through the stacked structure and the supporting structure. The semiconductor substrate and the stacked structure are connected through at least portions of the channel holes.

In further embodiments, the stacked structure may further include interlayer insulating layers alternatively stacked with the gate electrodes. The channel holes may extend through both the gate electrodes and the interlayer insulating layers.

In still further embodiments, a common source line is connected to the stacked structure and the semiconductor substrate.

In some embodiments, the interlayer insulating layers may not be removed from bottom surfaces of the channel holes due to presence of the supporting structure.

In further embodiments, the channel holes may include channel regions therein. The supporting structure may include horizontal parts at lower portions of the stacked structure and including areas in which the channel regions are horizontally elongated from the channel holes. The horizontal parts may surround respective channel holes and be connected to each other between at least a portion of the channel holes.

### BRIEF DESCRIPTION OF DRAWINGS

The above and other aspects, features, and advantages of the present inventive concept will be more clearly understood from the following detailed description taken in conjunction with the accompanying drawings, in which:

FIG. 1 is a schematic block diagram of a semiconductor device according to some embodiments the present inventive concept.

FIG. 2 is an equivalent circuit diagram illustrating a memory cell array of a semiconductor device according to some embodiments of the present inventive concept.

FIG. 3 is a plan view schematically illustrating a structure of memory cell strings of a semiconductor device according to some embodiments of the present inventive concept.

FIG. 4 is a cross section taken along line X-X′ of FIG. 3.

FIG. 5 is a partially cutaway perspective view illustrating only some configurations including a horizontal part of FIGS. 3 and 4.

FIGS. 6A and 6B are cross sections illustrating a horizontal part according to some embodiments of the present inventive concept.

FIGS. 7 and 8 are schematic cross sections of semiconductor devices according to some embodiments of the present inventive concept.

FIG. 9 is a schematic plan view illustrating a structure of memory cell strings of a semiconductor device according to some embodiments of the present inventive concept.

FIG. 10 is a cross section taken along line X-X′ of FIG. 9.

FIG. 11 is a schematic plan view illustrating a structure of memory cell strings of a semiconductor device according to some embodiments of the present inventive concept.

FIG. 12 is a cross section taken along line X-X′ of FIG. 11.

FIGS. 13A and 13B are schematic plan views illustrating a structure of memory cell strings of semiconductor devices according to some embodiments of the present inventive concept.

FIGS. 14A to 23 are diagrams illustrating processing steps in the fabrication of semiconductor devices according to some embodiments of the present inventive concept.

FIGS. 24A to 28B are diagrams illustrating processing steps in the fabrication of a semiconductor device according to some embodiments of the present inventive concept.

FIGS. 29A to 34B are diagrams illustrating processing steps in the fabrication of a semiconductor device according to some embodiments of the present inventive concept.

FIG. 35 is a perspective view schematically illustrating a semiconductor device according to some embodiments of the present inventive concept.

FIG. 36 is a block diagram illustrating a storage apparatus including a semiconductor device according to some embodiments of the present inventive concept.

FIG. 37 is a block diagram illustrating an electronic apparatus including a semiconductor device according to some embodiments of the present inventive concept.

FIG. 38 is a schematic diagram illustrating a system including a semiconductor device according to some embodiments of the present inventive concept.

### DETAILED DESCRIPTION

Hereinafter, embodiments of the present inventive concept will be described as follows with reference to the attached drawings.

The present inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the example embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present inventive concept will be described with reference to schematic views illustrating embodiments of the present inventive concept. In the drawings, for example, due to manufacturing techniques and/or tolerances, modifications of the shape shown may be estimated. Thus, embodiments of the present inventive concept should not be construed as being limited to the particular shapes of regions shown herein, for example, to include a change in shape results in manufacturing. The following embodiments may also be constituted by one or a combination thereof.

The contents of the present inventive concept described below may have a variety of configurations and propose only a required configuration herein, but are not limited thereto.

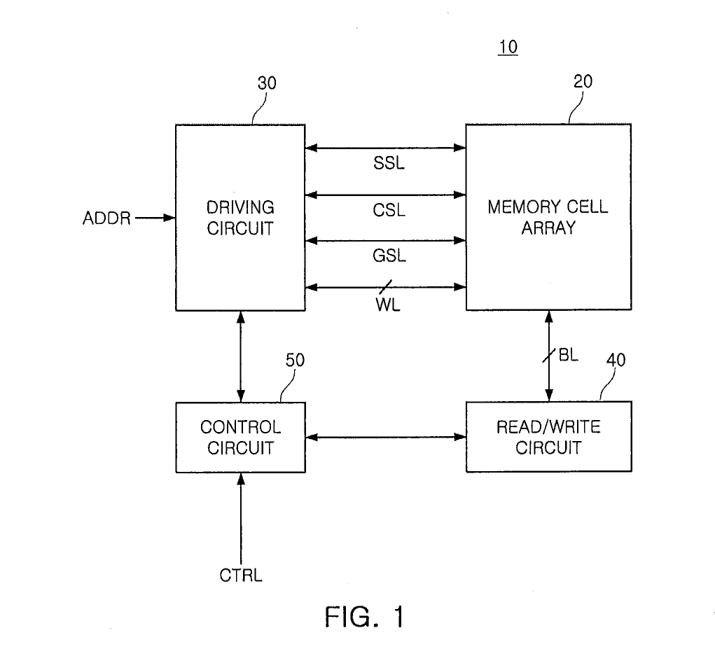

Referring first to FIG. 1, a schematic block diagram of a semiconductor device according to some embodiments of the present inventive concept will be discussed. As illustrated in FIG. 1, a semiconductor device 10 according to some embodiments may include a memory cell array 20, a driving circuit 30, a read/write circuit 40, and a control circuit 50.

The memory cell array 20 may include a plurality of memory cells, and the plurality of memory cells may be arranged in a plurality of rows and columns. The plurality of memory cells included in the memory cell array 20 may be connected to the driving circuit 30 via a word line WL, a common source line CSL, a string select line SSL, a ground select line GSL, and the like, and may be connected to the read/write circuit 40 via a bit line BL. In some embodiments, the plurality of memory cells arranged in the same row may be connected to the same word line WL, and the plurality of memory cells arranged in the same column may be connected to the same bit line BL.

The plurality of memory cells included in the memory cell array 20 may be divided into a plurality of memory blocks. Each memory block may include a plurality of word lines WL, a plurality of string select lines SSL, a plurality of ground select lines GSL, a plurality of bit lines BL, and at least one common source line CSL.

The driving circuit 30 and the read/write circuit 40 may be operated by the control circuit 50. In some embodiments, the driving circuit 30 may receive address information ADDR from an external source and decode the received address information ADDR to select at least a portion of the word lines WL, the common source line CSL, the string select lines SSL, and the ground select lines GSL connected to the memory cell array. The driving circuit 30 may include a circuit for driving each of the word lines WL, the string select lines SSL, and the common source line CSL.

The read/write circuit 40 may select at least a portion of the bit lines BL connected to the memory cell array 20 according to a command received from the control circuit 50. The read/write circuit 40 may read data stored in a memory cell connected to the selected portion of the bit lines BL, or may write data to the memory cell connected to the selected portion of the bit lines BL. The read/write circuit 40 may include circuits, such as a page buffer circuit, an input/output buffer circuit, a data latch circuit, and the like, in order to perform the above-described operations.

The control circuit 50 may control operations of the driving circuit 30 and the read/write circuit 40 in response to a control signal CTRL transmitted from an external source. When data stored in the memory cell array 20 is read, the control circuit 50 may control an operation of the driving circuit 30 so as to supply a voltage to the word line WL in which data to be read is stored for a reading operation. When the voltage for a reading operation is supplied to a specific word line WL, the control circuit 50 may control the read/write circuit 40 to read data stored in a memory cell connected to the word line WL to which the voltage for a reading operation is supplied.

Meanwhile, when data is to be written in the memory cell array 20, the control circuit 50 may control an operation of the driving circuit 30 so as to supply a voltage to a word line WL to which data is to be written in the writing operation. When the voltage for the writing operation is supplied to a specific word line WL, the control circuit 50 may control the read/write circuit 40 to write data to a memory cell connected to the word line WL to which the voltage for the writing operation is supplied.

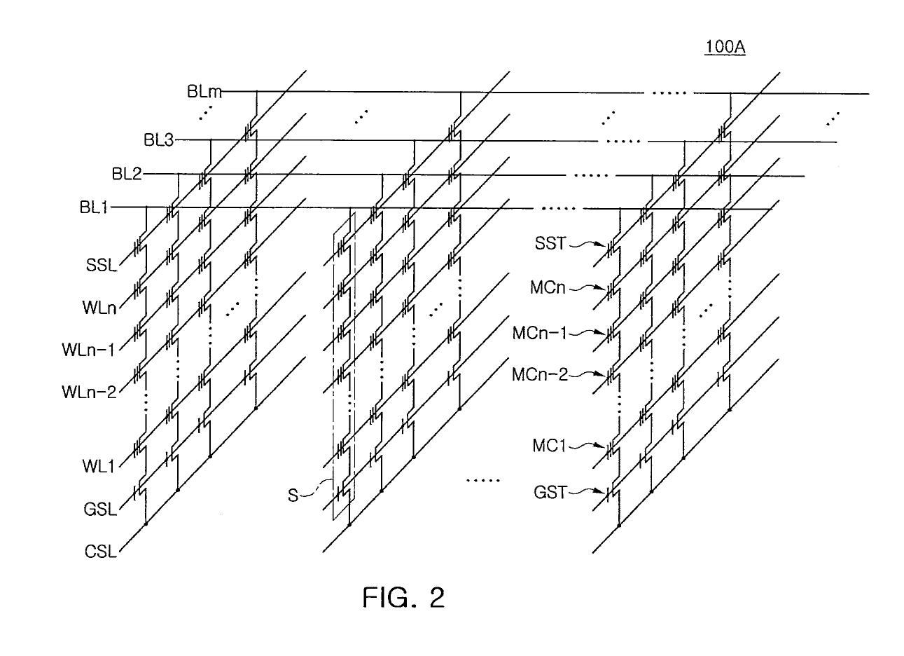

Referring now to FIG. 2, an equivalent circuit diagram illustrating a memory cell array of a semiconductor device according to some embodiments of the present inventive concept will be discussed. FIG. 2 is an equivalent circuit diagram illustrating a three-dimensional structure of a memory cell array included in a vertical semiconductor device 100A. As illustrated in FIG. 2, the memory cell array according to some embodiments may include a plurality of memory cell strings S. Each of the memory cell strings S includes n memory cell devices MC1 to MCn connected to each other in series, and a ground select transistor GST and a string select transistor SST respectively connected to both ends of the memory cell devices MC1 to MCn in series.

The n memory cell devices MC1 to MCn connected to each other in series may be respectively connected to word lines WL1 to WLn for selecting at least a portion of the memory cell devices MC1 to MCn.

A gate terminal of the ground select transistor GST may be connected to a ground select line GSL, and a source terminal of the ground select transistor GST may be connected to a common source line CSL. Meanwhile, a gate terminal of the string select transistor SST may be connected to a string select line SSL, and a source terminal of the string select transistor SST may be connected to a drain terminal of a memory cell device MCn. As illustrated in FIG. 2, one ground select transistor GST and one string select transistor SST are connected to the n memory cell devices MC1 to MCn connected to each other in series. However, a plurality of ground select transistors GST or a plurality of string select transistors SST may be connected to the n memory cell devices MC1 to MCn.

A drain terminal of the string select transistor SST may be connected to a plurality of bit lines BL1 to BLm. When a signal is applied to the gate terminal of the string select transistor SST via the string select line SSL, the signal applied via the bit lines BL1 to BLm is transmitted to the n memory cell devices MC1 to MCn connected to each other in series, and a data reading or data writing operation may be performed.

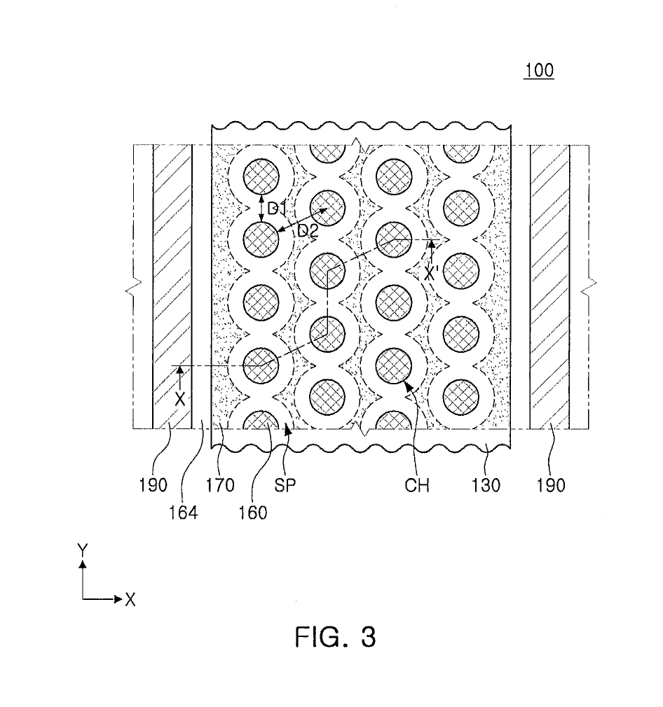

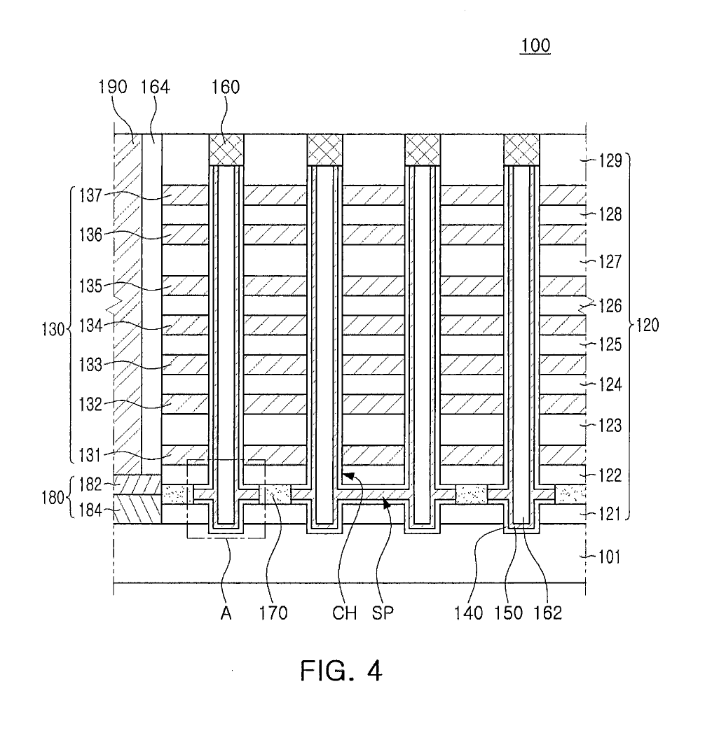

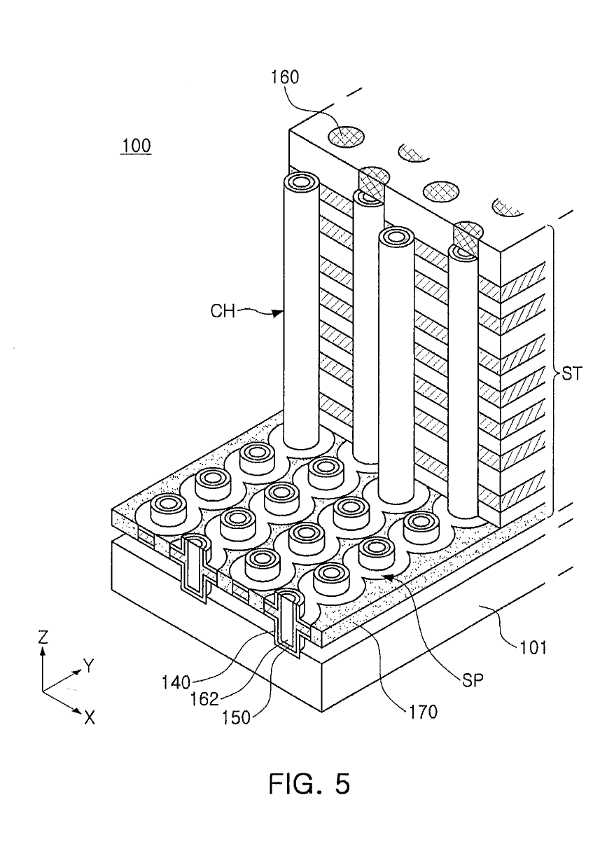

FIG. 3 is a plan view schematically illustrating a structure of memory cell strings of a semiconductor device according to some embodiments of the present inventive concept, FIG. 4 is a cross section taken along line X-X′ of FIG. 3, and FIG. 5 is a partially cutaway perspective view illustrating only some configurations including a horizontal portion in FIGS. 3 and 4.

Referring now to FIGS. 3 through 5, a semiconductor device 100 may include a substrate 101, channel holes CH extending in a direction perpendicular to an upper surface of the substrate 101 and including a plurality of channel regions 150 disposed therein, horizontal parts SP disposed on the substrate 101 and including portions formed by horizontally elongated channel regions 150, horizontal filling layers 170 disposed outwardly of the horizontal parts SP, and a plurality of interlayer insulating layers 120 and gate electrodes 130 stacked on outer sidewalls of the channel regions 150.

The semiconductor device 100 may further include a gate dielectric layer 140, channel pads 160, a contact line 180, and a conductive layer 190. In FIGS. 3 and 4, some components, such as upper interconnection structures such as bit lines BL1 to BLm (refer to FIG. 2) are omitted. Furthermore, some components, such as interlayer insulating layers 120, among the components illustrated in FIG. 4 are omitted in FIG. 3.

In the semiconductor device 100, one memory cell string may be configured around each channel region 150, and a plurality of memory cell strings may be arranged to form rows and columns in an x-axis direction and a y-axis direction.

The substrate 101 may include the upper surface extending in the x-axis direction and the y-axis direction. The substrate 101 may include a semiconductor material. For example, the substrate 101 may be a Group IV semiconductor, a Group III-V compound semiconductor, or a Group II-VI oxide semiconductor. For example, the Group IV semiconductor may include silicon, germanium, or silicon-germanium. The substrate 101 may be provided in the form of a bulk wafer or an epitaxial layer.

The pillar-shaped channel regions 150 may be disposed in the channel hole CH extending in a direction perpendicular to the upper surface of the substrate 101. The channel regions 150 may be formed in an annular shape surrounding a first insulating layer 162. In some embodiments, the channel regions 150 may have a pillar shape, such as a cylindrical or prismatic shape without first insulating layer 162. The channel regions 150 may have an inclined side surface and, thus, a width thereof may decrease toward the substrate 101, depending on an aspect ratio thereof.

The channel regions 150 may be spaced apart from each other in rows and columns on the substrate 101 according to the arrangement of the channel holes CH illustrated in FIG. 3, and may be arranged to be shifted from each other in the x-axis direction. In other words, the channel regions 150 may be arranged to form a grid pattern or a zigzag pattern in one direction. However, the arrangement of the channel regions 150 may be changed according to some embodiments, and is not limited to that illustrated in FIG. 3.

The channel regions 150 may be isolated and insulated from the substrate 101 at bottoms thereof by the gate dielectric layer 140. The channel regions 150 may include a semiconductor material, such as polysilicon or single crystalline silicon, and the semiconductor material may be an undoped material or may include p-type or n-type impurities.

The plurality of gate electrodes 130 (131 to 137) may be arranged on respective side surfaces of the channel regions 150 and spaced apart in a direction perpendicular to the substrate 101. As further illustrated in FIG. 2, each of the gate electrodes 130 may form a gate of the ground select transistor GST, the plurality of memory cell devices MC1 to MCn, or the string select transistor SST. The gate electrodes 130 may extend to form the word lines WL1 to WLn, and may be commonly connected by a predetermined unit of adjacent memory cell strings S arranged in the x-axis direction and the y-axis direction. In some embodiments of the inventive concept, four gate electrodes 132 to 135 of the memory cell devices MC1 to MCn are arranged, but the present inventive concept is not limited thereto. Depending on the capacity of the semiconductor device 100, the number of the gate electrodes 130 of the memory cell devices MC1 to MCn may be determined. For example, the number of gate electrodes 130 forming the memory cell devices MC1 to MCn may be 2ⁿ (in which n is a natural number).

A gate electrode 131 of the ground select transistors GST may extend in the y-axis direction to form the ground select lines GSL. Gate electrodes 136 and 137 of the string select transistors SST may extend in the y-axis direction to form the string select lines SSL. Adjacent memory cell strings arranged in a line in the x-axis direction may be respectively connected to different bit lines BL1 to BLm by an additional interconnection structure. In some embodiments, gate electrodes 136 and 137 of the string select transistors SST may be separated from each other between the adjacent memory cell strings S in the x-axis direction to form different string select lines SSL. In some embodiments, one or more gate electrodes 136 and 137 of the string select transistors SST, and one or more gate electrodes 131 of the ground select transistors GST may be disposed, and may have structures the same as or different from those of the gate electrodes 132 to 135 of the memory cell devices MC1 to MCn.

Some of the gate electrodes 130, such as the gate electrodes disposed adjacent to the gate electrode 131 of the ground select transistors GST or the gate electrodes 136 and 137 of the string select transistors SST, may be dummy gate electrodes. For example, the gate electrode 132 disposed adjacent to the gate electrode 131 of the ground select transistors GST may be dummy gate electrodes.

The gate electrodes 130 may include polysilicon or a metal silicide material. The metal silicide material may be, for example, a silicide material of a metal selected from cobalt (Co), nickel (Ni), halfnium (Hf), platinum (Pt), tungsten (W), and titanium (Ti), or a combination thereof. In some embodiments, the gate electrodes 130 may include a metal such as W. Although not illustrated in the drawings, the gate electrodes 130 may further include a diffusion barrier layer. For example, the diffusion barrier layer may include WN, TaN, TiN, or a combination thereof.

The plurality of interlayer insulating layers 120 (121 to 129) may be arranged between the gate electrodes 130. The interlayer insulating layers 120, like the gate electrodes 130, may be arranged to be spaced apart from each other in a direction perpendicular to the upper surface of the substrate 101. The interlayer insulating layers 120 may include an insulating material, such as silicon oxide or silicon nitride.

The gate dielectric layer 140 may be disposed between the gate electrodes 130 and the channel regions 150 in the channel holes CH. The gate dielectric layer 140 may vertically extend from the substrate 101 along the channel regions 150. The gate dielectric layer 140 may cover bottom surfaces of the channel holes CH.

The gate dielectric layer 140 may include a tunneling layer, a charge storage layer, and a blocking layer sequentially stacked on the channel regions 150. In some embodiments, at least one of the layers configuring the gate dielectric layer 140, such as the blocking layer, may not vertically extend on the channel regions 150 and may extend on upper and lower surfaces of the gate electrodes 130.

The tunneling layer may allow charges to be tunneled into the charge storage layer by an F-N tunneling mechanism. The tunneling layer may include, for example, silicon dioxide (SiO₂), silicon nitride (Si₃N₄), silicon oxynitride (SiON), or a combination thereof.

The charge storage layer may be a charge trapping layer or a floating gate conductive layer. For example, the charge storage layer may include a dielectric material, quantum dots, or nanocrystals. In these embodiments, the quantum dots or nanocrystals may be formed of nanoparticles of a conductive material, such as a metal or a semiconductor material. In some example embodiments, when the charge storage layer is the charge trapping layer, the charge storage layer may be formed of silicon nitride.

The blocking layer may include silicon dioxide (SiO₂), silicon nitride (Si₃N₄), silicon oxynitride (SiON), a high-k dielectric material, or a combination thereof. The high-k dielectric material may be one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The horizontal parts SP and the horizontal filling layers 170 may be disposed between two lowermost insulating layers 121 and 122 on the substrate 101. As illustrated in FIG. 5, the horizontal parts SP and the horizontal filling layers 170 may be disposed at a lower portion of a stacked structure ST including the gate electrodes 130.

The horizontal parts SP may be connected to the channel holes CH and disposed to be parallel to the upper surface of the substrate 101, and may be connected to each other between some of the channel holes CH. As illustrated in FIG. 3, the horizontal parts SP may be connected to each other between the channel holes CH adjacent to each other in one direction. However, it will be understood that embodiments of the present inventive concept are not limited to this configuration.

The horizontal parts SP may have a circular shape surrounding respective channel holes CH in which the channel regions 150 are formed, and may be connected to each other between some of the channel holes CH, as illustrated in FIG. 3. The channel holes CH adjacent to each other in one direction may be spaced apart by a first distance D1 in a direction in which the horizontal parts SP are connected to each other, and by a second distance D2 greater than the first distance D1 in a direction in which the horizontal parts SP are not connected to each other.

The horizontal parts SP may be formed as portions of the gate dielectric layer 140 and the channel regions 150. In other words, the horizontal parts SP may be formed in areas in which the gate dielectric layer 140 and the channel regions 150 horizontally extend from the channel holes CH. In the horizontal parts SP, the gate dielectric layer 140 may be disposed on upper and lower surfaces of the channel regions 150, and may not cover the channel regions 150 on side surfaces of the horizontal parts SP. Accordingly, the channel regions 150 may be in contact with the horizontal filling layers 170 on the side surfaces of the horizontal parts SP.

The horizontal filling layers 170 may fill spaces between the horizontal parts SP, and may be parallel to the horizontal parts SP. In other words, as illustrated in FIG. 5, the horizontal filling layers 170, together with the horizontal parts SP, may form a layer parallel to the upper surface of the substrate 101.

The horizontal filling layers 170 may surround the side surfaces of the horizontal parts SP between the adjacent conductive layers 190. In some embodiments, the horizontal filling layers 170 may be connected to each other to form a single layer. For example, the horizontal filling layers 170 may be connected in a region (not illustrated in the drawings) in the y-axis direction.

The horizontal filling layers 170 may be formed of, for example, a conductive material, such as a semiconductor material, however, it will be understood that embodiments of the present inventive concept are not limited to this configuration. At upper ends of the memory cell strings, the channel pads 160 may be disposed to cover upper surfaces of the first insulating layers 162 and electrically connected to the channel regions 150. The channel pads 160 may include, for example, doped polysilicon. The channel pads 160 may function as drain region of the string select transistors SST (refer to FIG. 2). The channel pads 160 may be electrically connected to the bit lines BL1 to BLm (refer to FIG. 2) via contact plugs or the like.

The contact line 180 may be disposed between the channel regions 150 on the substrate 101. The conductive layer 190 may be disposed on the contact line 180, and may be electrically isolated from the gate electrodes 130 by the second insulating layer 164. A width of the conductive layer 190 may be narrowed toward the substrate 101 due to a high aspect ratio thereof. The contact line 180 and the conductive layer 190 may have a line shape extending in the y-axis direction. The contact line 180 and the conductive layer 190 may be arranged for every two or four columns of the channel regions 150 in the x-axis direction, but are not limited thereto.

The contact line 180 may include a vertically arranged first impurity area 182 and a second impurity area 184. The first and second impurity areas 182 and 184 may include different types of conductivity-type impurities. For example, the first impurity area 182 may include impurities different from the conductivity-type impurities of the substrate 101, and the second impurity area 184 may include impurities the same as the conductivity-type impurities of the substrate 101 with a higher concentration than that of the substrate 101. When the semiconductor device 100 is operated, electrons may flow between the channel region 150 and the conductive layer 190 via the first impurity area 182 and the horizontal filling layers 170, and holes may flow between the channel region 150 and the substrate 101 via the second impurity area 184 and the horizontal filling layers 170. In these embodiments, the first and second impurity areas 182 and 184 may be connected to different interconnections in a region (not illustrated in the drawings). However, the structure and function of the contact line 180 are not limited thereto, and the contact line 180 may have a different structure according to areas in the semiconductor device 100. In some embodiments, the contact line 180 may configure the common source line CSL of FIG. 2, and may include only one impurity area.

The contact line 180 may be formed of, for example, a semiconductor material, and the conductive layer 190 may include a metal such as tungsten (W), aluminum (Al), or copper (Cu).

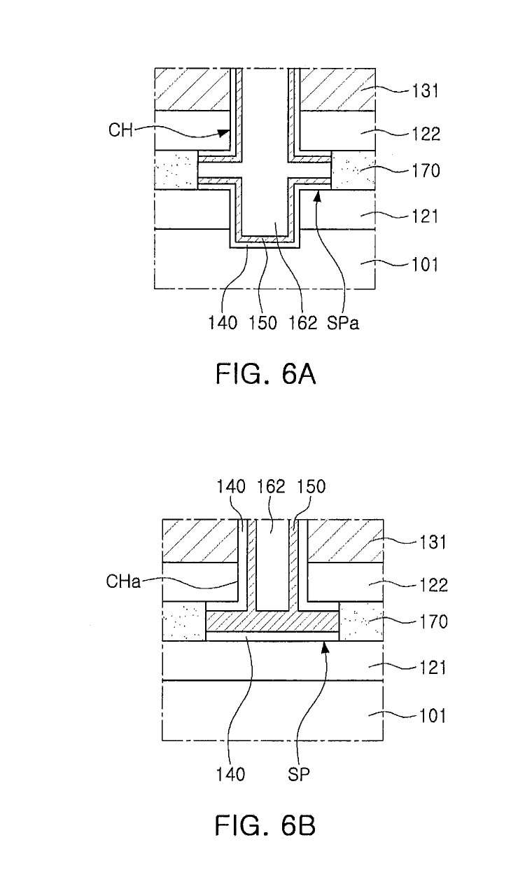

FIGS. 6A and 6B are cross sections illustrating a horizontal part according to embodiments of the present inventive concept, which illustrate a portion corresponding to area ‘A’ of FIG. 4.

Referring first to FIG. 6A, a gate dielectric layer 140, channel regions 150, and a first insulating layer 162 disposed in a channel hole CH and a horizontal part SPa, and a horizontal filling layer 170 will be discussed.

The horizontal part SPa according to some embodiments may further include the first insulating layer 162, unlike the horizontal part SP illustrated in FIG. 4. In other words, the horizontal part SPa may include the gate dielectric layer 140, the channel region 150, and the first insulating layer 162 between the channel regions 150. Such a structure may be formed in such a manner that, when the horizontal part SPa is relatively thick or the channel region 150 is relatively thin, the channel region 150 is uniformly deposited on the gate dielectric layer 140 in the horizontal part SPa in such a manner that an upper portion and a lower portion of the channel region 150 are separated, and the first insulating layer 162 fills a space between the upper and lower portions thereof.

Referring now to FIG. 6B, a gate dielectric layer 140, a channel region 150, and a first insulating layer 162 disposed in a channel hole CHa and a horizontal part SP, and a horizontal filling layer 170 will be discussed.

The channel hole CHa according to some embodiments may extend to the lowermost interlayer insulating layer 121 but not to the substrate 101, unlike those in some embodiments illustrated in FIGS. 4 and 6A. Accordingly, a bottom of the channel hole CHa and a bottom of the horizontal part SP may be coplanar and may horizontally extend. In some embodiments, the channel hole CHa may extend into a portion of the lowermost interlayer insulating layer 121.

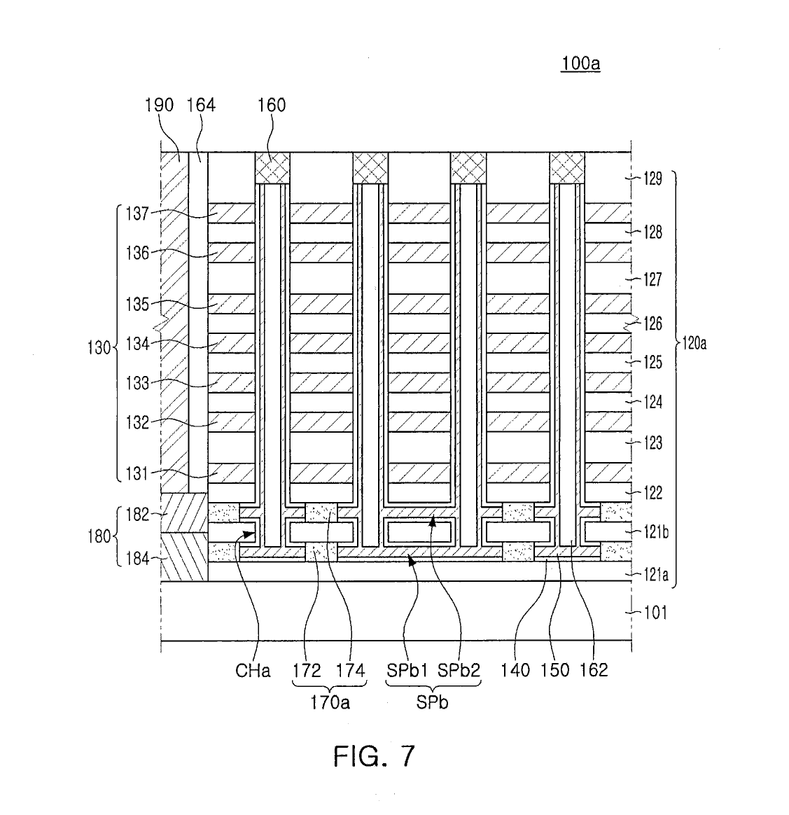

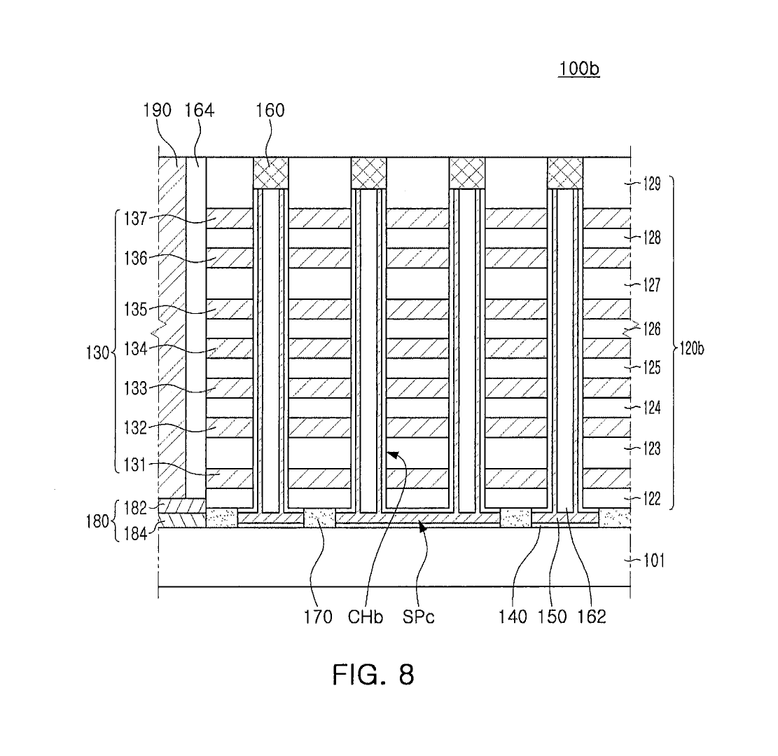

FIGS. 7 and 8 are schematic cross sections of semiconductor devices according to some embodiments of the present inventive concept. Referring first to FIG. 7, the semiconductor device 100a may include a substrate 101, a plurality of channel regions 150 disposed in a direction perpendicular to an upper surface of the substrate 101, horizontal parts SPb connected to the channel regions 150 on the substrate 101, horizontal filling layers 170a disposed outwardly of the horizontal parts SPb, and a plurality of interlayer insulating layers 120a and a plurality of gate electrodes 130 stacked on outer sidewalls of the channel regions 150. The semiconductor device 100a may further include gate dielectric layers 140, channel pads 160, a contact line 180, and a conductive layer 190.

The horizontal part SPb according to some embodiments may include first and second horizontal parts SPb1 and SPb2 spaced apart from each other in a direction perpendicular to the substrate 101. Accordingly, the horizontal filling layer 170a may include first and second horizontal filling layers 172 and 174 respectively disposed at outwardly portions of the first and second horizontal parts SPb1 and SPb2. An interlayer insulating layer 121b may be disposed between the first and second horizontal parts SPb1 and SPb2. The gate dielectric layers 140 and the channel regions 150 may be vertically connected to each other between the first and second horizontal parts SPb1 and SPb2.

In some embodiments, channel holes CHa are illustrated to extend only onto the lowermost interlayer insulating layer 121a. However, in some embodiments, the channel holes CHa may extend and recess the substrate 101 as those in some embodiments described with reference to FIG. 4, or may extend to the substrate 101.

The first and second horizontal parts SPb1 and SPb2 may be connected to first and second impurity areas 182 and 184 of the contact line 180, respectively. Thereby, holes may flow via the lower first horizontal part SPb1, and electrons may flow via the upper second horizontal part SPb2. However, it will be understood that the structure of the contact line 180 is not limited to this configuration.

Referring to FIG. 8, a semiconductor device 100b may include a substrate 101, a plurality of channel regions 150 disposed perpendicular to an upper surface of the substrate 101, horizontal parts SPc connected to the channel regions 150 on the substrate 101, horizontal filling layers 170 disposed outwardly of the horizontal parts SPc, and a plurality of interlayer insulating layers 120b and a plurality of gate electrodes 130 stacked on outer sidewalls of the channel regions 150. The semiconductor device 100b may further include gate dielectric layers 140, channel pads 160, a contact line 180, and a conductive layer 190.

The horizontal parts SPc according to some embodiments may be disposed on the substrate 101 to be in contact with the substrate 101 not on the interlayer insulating layers 120b, unlike those in some embodiments illustrated in FIG. 4. In other words, the interlayer insulating layers 120b may not be disposed below the horizontal parts SPc.

Although channel holes CHb are illustrated to extend only onto the substrate 101 in some embodiments, the channel holes CHb may extend to recess the substrate 101 as illustrated in some embodiments of FIG. 4.

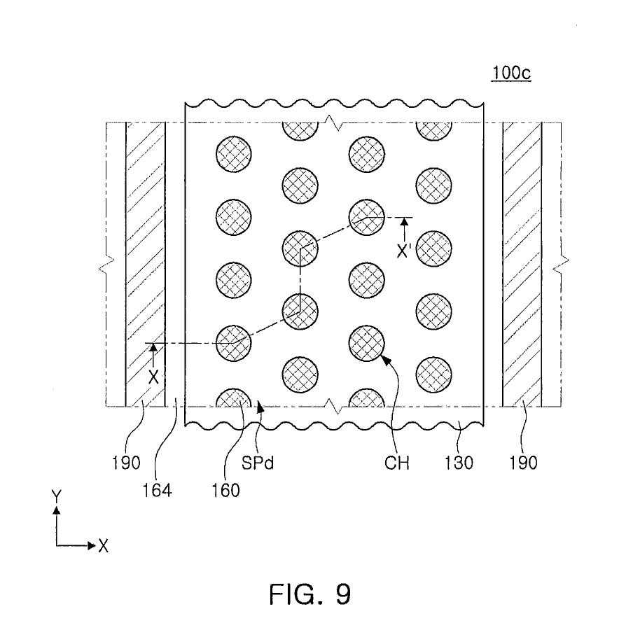

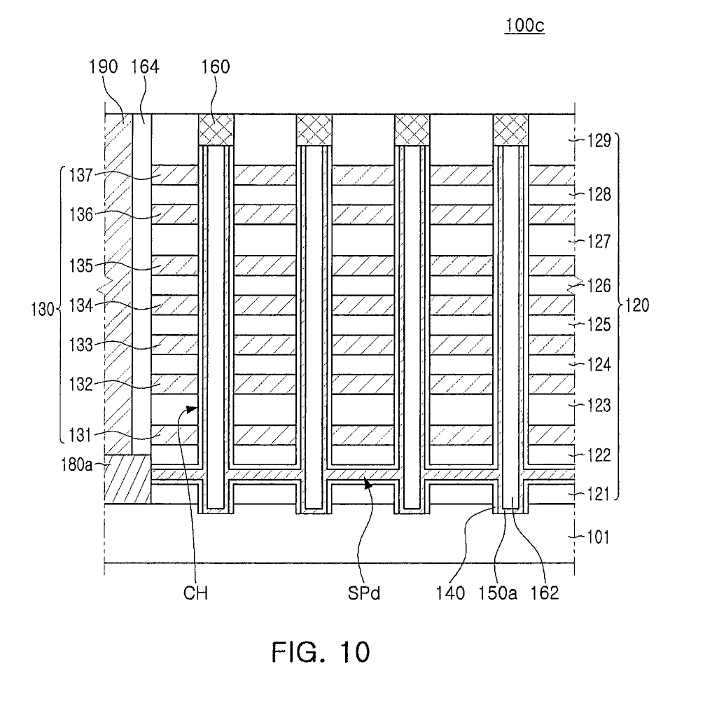

FIG. 9 is a schematic plan view illustrating a structure of memory cell strings of a semiconductor device according to some embodiments of the present inventive concept, and FIG. 10 is a cross section taken along line X-X′ of FIG. 9.

Referring to FIGS. 9 and 10, the semiconductor device 100c may include a substrate 101, a plurality of channel regions 150a disposed perpendicular to an upper surface of the substrate 101, horizontal parts SPd connected to the channel regions 150a on the substrate 101, and a plurality of interlayer insulating layers 120 and a plurality of gate electrodes 130 stacked on outer sidewalls of the channel regions 150a. The semiconductor device 100c may further include gate dielectric layers 140, channel pads 160, a contact line 180a, and a conductive layer 190.

In some embodiments, first, the channel regions 150a may be in direct contact with the substrate 101 at bottoms of channel holes CH, unlike those in some embodiments illustrated in FIG. 4. In other words, the channel regions 150a may form lower surfaces of the channel holes CH.

Furthermore, the horizontal filling layers 170 disposed outwardly of the horizontal parts SP in FIGS. 3 and 4 may be omitted in some embodiments. Accordingly, the horizontal parts SPd may extend to areas in which the contact line 180a and the conductive layer 190 are formed, and may form one layer connected to each other between the contact lines 180a and the conductive layers 190 adjacent to each other.

Furthermore, the contact lines 180a according to some embodiments may be formed to include only one kind of conductivity-type impurities, however, it will be understood that embodiments of the present inventive concept are not limited thereto. In some embodiments, the contact lines 180a may be omitted. In these embodiments, impurity areas may be formed on the substrate 101, and the conductive layer 190 may extend to the impurity areas of the substrate 101.

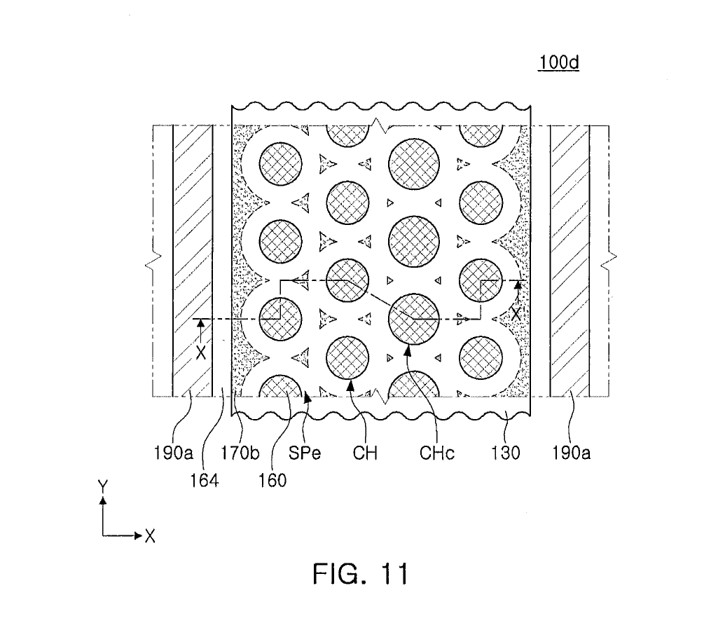

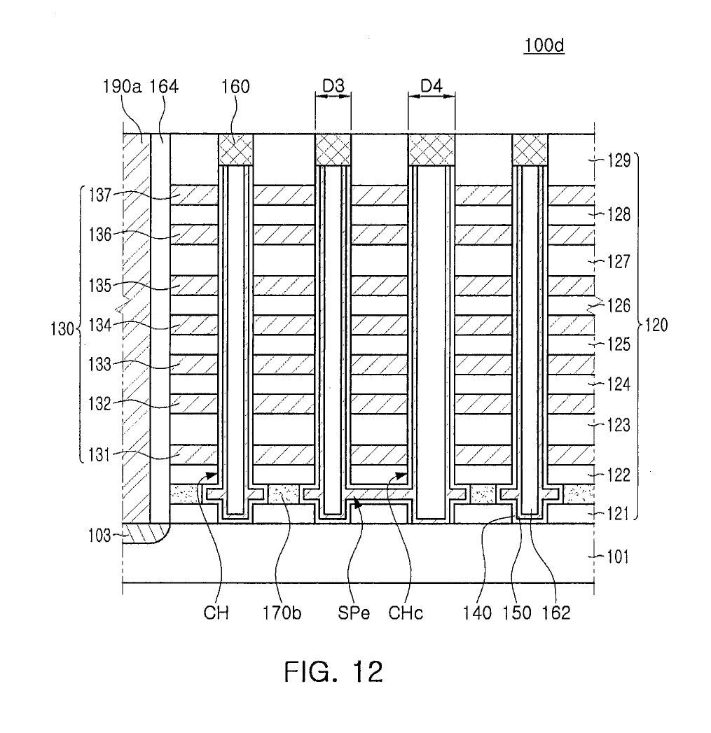

FIG. 11 is a schematic plan view illustrating a structure of memory cell strings of a semiconductor device according to some embodiments of the present inventive concept, and FIG. 12 is a cross section taken along line X-X′ of FIG. 11.

Referring to FIGS. 11 and 12, a semiconductor device 100d may include a substrate 101, a plurality of channel regions 150 disposed perpendicular to an upper surface of the substrate 101, horizontal parts SPe connected to the channel regions 150 on the substrate 101, horizontal filling layers 170b disposed outwardly of the horizontal parts SPe, and a plurality of interlayer insulating layers 120 and a plurality of gate electrodes 130 stacked on outer sidewalls of the channel regions 150. The semiconductor device 100d may further include gate dielectric layers 140, channel pads 160, an impurity area 103, and a conductive layer 190a.

In some embodiments, a row of channel holes CHc arranged in the y-axis direction may be greater than other channel holes CH. The row of channel holes CHc may have a size such as a diameter D4 greater than a diameter D3 of other channel holes CH. The row of channel holes CHc may allow the channel regions 150 to be in direct contact with the substrate 101 at bottoms thereof, and the channel regions 150 of the other channel holes CH may not be in direct contact with the substrate 101 due to the gate dielectric layer 140. The arrangement of the channel holes CHc is not limited thereto. In some embodiments, the channel holes CHc may not be arranged in a row and may be arranged at predetermined distances.

Furthermore, as illustrated in FIG. 11, the horizontal parts SPe may be connected in a circular shape surrounding the channel regions 150 and may form one layer. Accordingly, the horizontal filling layers 170b may be disposed between adjacent channel regions 150, and may have a rounded triangle shape surrounded and isolated by the horizontal parts SPe.

Furthermore, the contact line 180 illustrated in FIG. 4 may be omitted in some embodiments. The impurity area 103 may be disposed on the substrate 101, and the conductive layer 190a may extend to the impurity area 103. In some embodiments, the conductive layer 190a may function as the common source line CSL illustrated in FIG. 2 and the channel holes CHc having the relatively large diameter D4 may function as contacts with the substrate 101, but are not limited thereto.

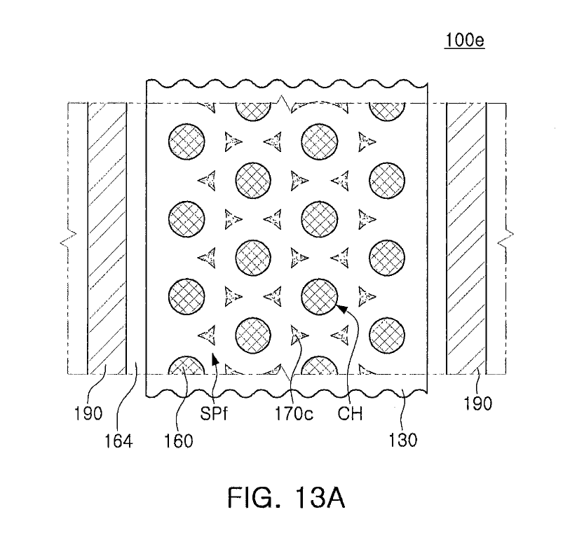

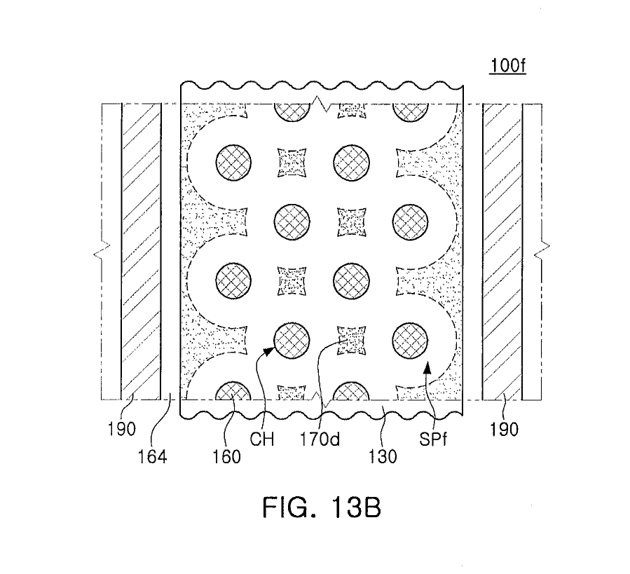

FIGS. 13A and 13B are schematic plan views illustrating a structure of memory cell strings of semiconductor devices according to some embodiments of the present inventive concept.

Referring to FIG. 13A, in a semiconductor device 100e, horizontal parts SPf may have a shape similar to those in some embodiments illustrated in FIG. 11, or may extend to a side of an area in which the conductive layer 190 is disposed, unlike those in the some embodiments illustrated in FIG. 11. Accordingly, the horizontal filling layers 170c may be disposed between channel regions 150 and only formed as areas surrounded and isolated by the horizontal parts SPf.

Referring to FIG. 13B, in the semiconductor device 100f, horizontal filling layers 170d may have a different shape from the horizontal filling layers 170c in the some embodiments described with reference to FIG. 13A, depending on the arrangement of channel holes CH. As illustrated in FIG. 13B, since the arrangement of the channel holes CH is different, the horizontal filling layers 170d may have a rounded tetragonal shape isolated between four adjacent channel regions 150. Accordingly, the horizontal filling layers 170d in FIG. 13B may have a different shape from the horizontal filling layers 170c formed between three adjacent channel regions 150 in FIG. 13A.

In some embodiments, the horizontal parts SPf may extend to a side of an area in which the conductive layer 190 is disposed, as illustrated in FIG. 13A.

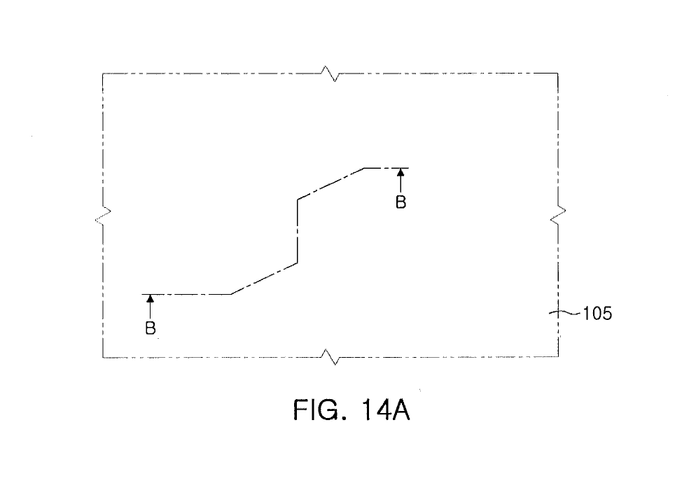

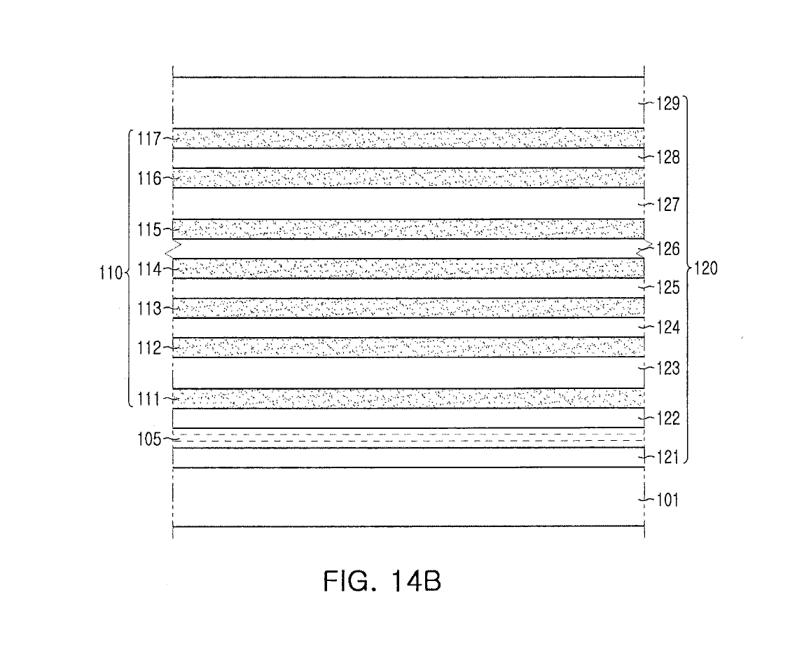

FIGS. 14A to 23 are process views schematically illustrating main processes in fabricating a semiconductor device according to some embodiments of the present inventive concept. In FIGS. 14A to 23, a method of fabricating the semiconductor device 100 illustrated in FIGS. 3 and 4 may be described, and regions corresponding to those illustrated in FIGS. 3 and 4 may be illustrated.

Hereinafter, in plan views illustrating methods of fabricating semiconductor devices, such as FIGS. 14A to 34A, components arranged around channel holes CH, such as second sacrificial layers 110, interlayer insulating layers 120, gate electrodes 130, In other words, components disposed on areas corresponding to horizontal parts SP, are omitted for easier understanding of the present inventive concept.

Referring to FIGS. 14A and 14B, a first sacrificial layer 105 and second sacrificial layers 110 (111 to 118), and interlayer insulating layers 120 may be alternately stacked on a substrate 101. In a subsequent process, the first sacrificial layer 105 may be replaced by horizontal parts SP and horizontal filling layers 170, and the second sacrificial layers 110 may be replaced by gate electrodes 130.

First, starting with a first interlayer insulating layer 121, the interlayer insulating layers 120 and the first and second sacrificial layers 105 and 110 may be alternately stacked on the substrate 101, as illustrated in FIG. 14B. The first and second sacrificial layers 105 and 110 may be formed of materials having etch selectivities with respect to the interlayer insulating layers 120. In other words, the first and second sacrificial layers 105 and 110 may be formed of materials capable of being etched during a process of etching the first and second sacrificial layers 105 and 110 while minimizing etching of the interlayer insulating layers 120. Such etch selectivities may be quantitatively expressed as a ratio of an etch rate of the first and second sacrificial layers 105 and 110 to an etch ratio of the interlayer insulating layers 120. For example, the interlayer insulating layers 120 may be formed of at least one of silicon oxide and silicon nitride, and the first and second sacrificial layers 105 and 110 may be formed of a different material from the interlayer insulating layers 120, among the materials selected from silicon, silicon oxide, silicon carbide, and silicon nitride. The first sacrificial layer 105 may be formed of a material having an etch selectivity with respect to the second sacrificial layers 110. For example, the first sacrificial layer 105 may be polysilicon, and the second sacrificial layers 110 may be silicon nitride.

As illustrated in FIG. 14B, the interlayer insulating layers 120 may have different thicknesses. In the interlayer insulating layers 120, the lowermost interlayer insulating layer 121 may be relatively thin, and the uppermost interlayer insulating layer 129 may be relatively thick. In some embodiments, interlayer insulating layers 123 and 127 disposed between the ground select transistor GST and the memory cell devices MC1 to MCn and between the string select transistor SST and the memory cell devices MC1 to MCn in FIG. 2 may be thicker than interlayer insulating layers 124 to 126 disposed between the memory cell devices MC1 to MCn. The thicknesses of the interlayer insulating layers 120 and the first and second sacrificial layers 105 and 110 may be variously modified from those illustrated in FIG. 14B. The numbers of the interlayer insulating layers 120 and the first and second sacrificial layers 105 and 110 may be variously changed, too.

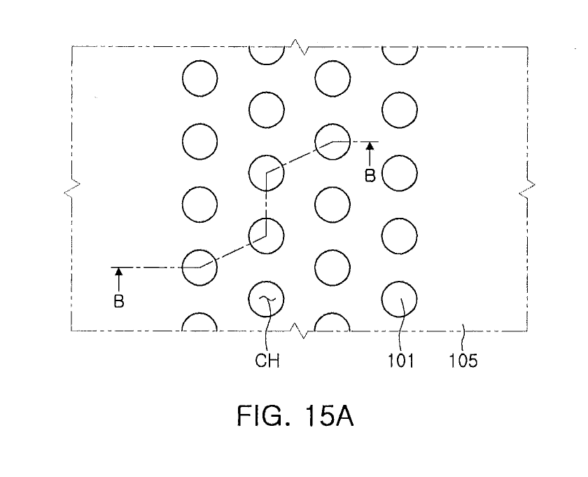

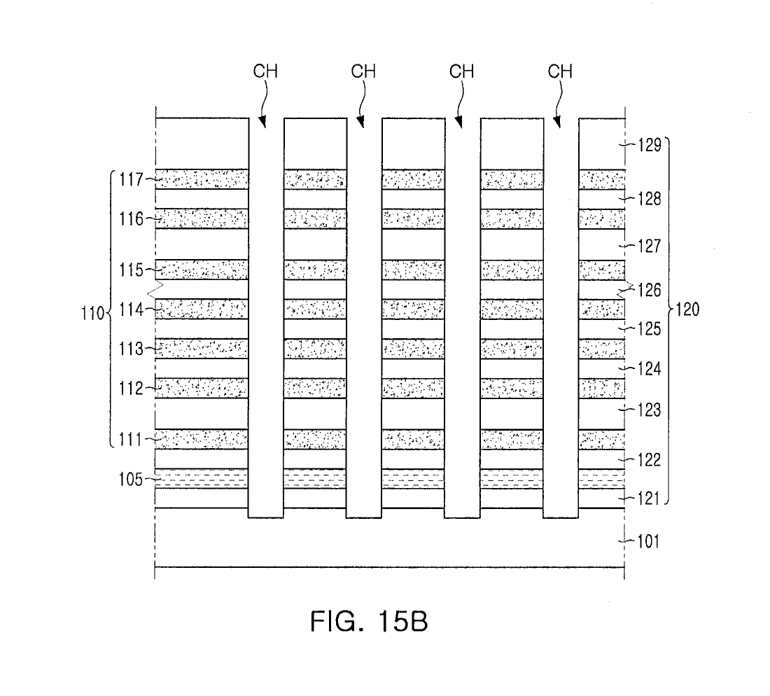

Referring to FIGS. 15A and 15B, channel holes CH extending perpendicularly with respect to the substrate 101 may be formed.

The channel holes CH may be formed by anisotropically etching a stacked structure including the first and second sacrificial layers 105 and 110 and the interlayer insulating layers 120. Since a structure including different types of layers is etched, sidewalls of the channel holes CH may not be perpendicular to an upper surface of the substrate 101. For example, widths of the channel holes CH may be decreased toward the upper surface of the substrate 101. The substrate 101 may be partially recessed by the channel holes CH.

In some embodiments, the channel holes CH may not recess the substrate 101. In these embodiments, the channel holes CH may extend to an upper surface of the first sacrificial layer 105 or into the first sacrificial layer 105 so as to expose at least the first sacrificial layer 105.

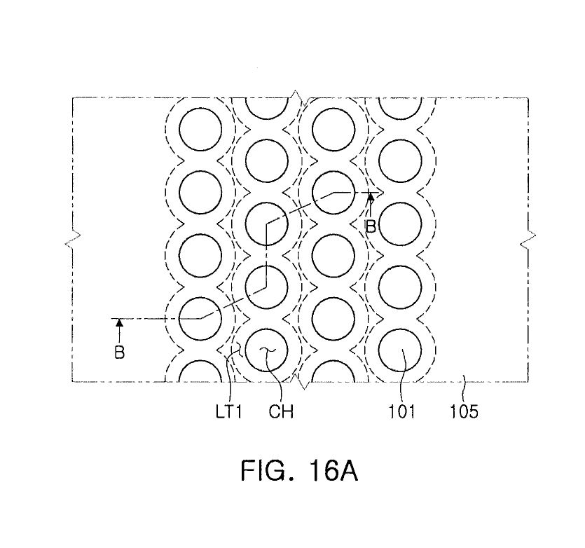

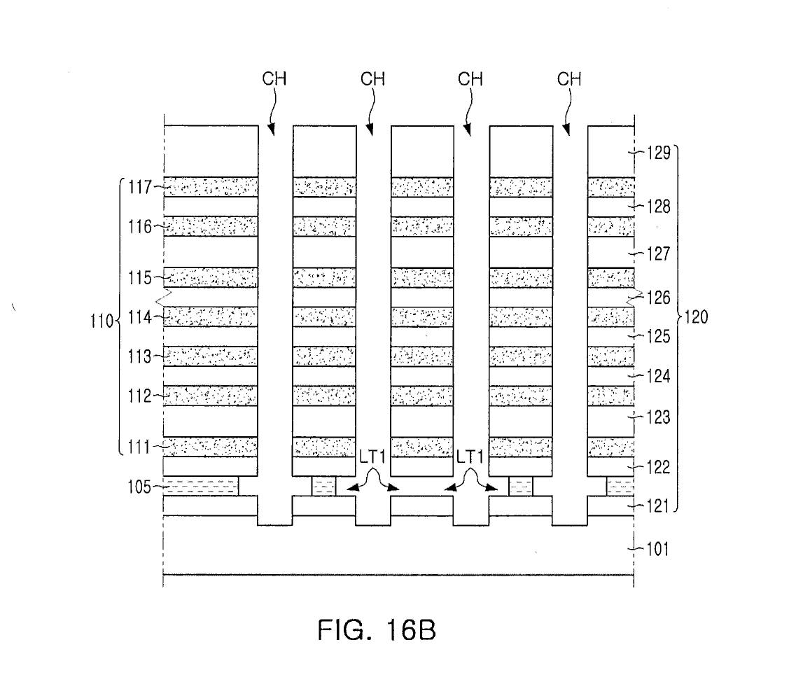

Referring to FIGS. 16A and 16B, the first sacrificial layer 105 may be partially removed through the channel holes CH to form first horizontal tunnels LT1. The first sacrificial layer 105 may be selectively removed by a dry etching process, such as a gas phase etching (GPE) process, while the interlayer insulating layers 120 and the second sacrificial layers 110 remain. The first sacrificial layer 105 may be partially etched to a predetermined distance from the channel holes CH by controlling process conditions such as process time.

In this process, the first horizontal tunnels LT1 may be formed, and thus a stacked structure of the interlayer insulating layers 120 and the second sacrificial layers 110 disposed on the first horizontal tunnels LT1 may be supported by the remaining first sacrificial layer 105.

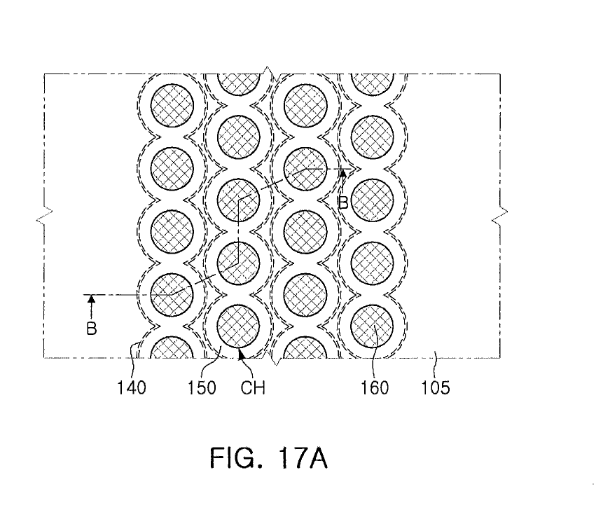

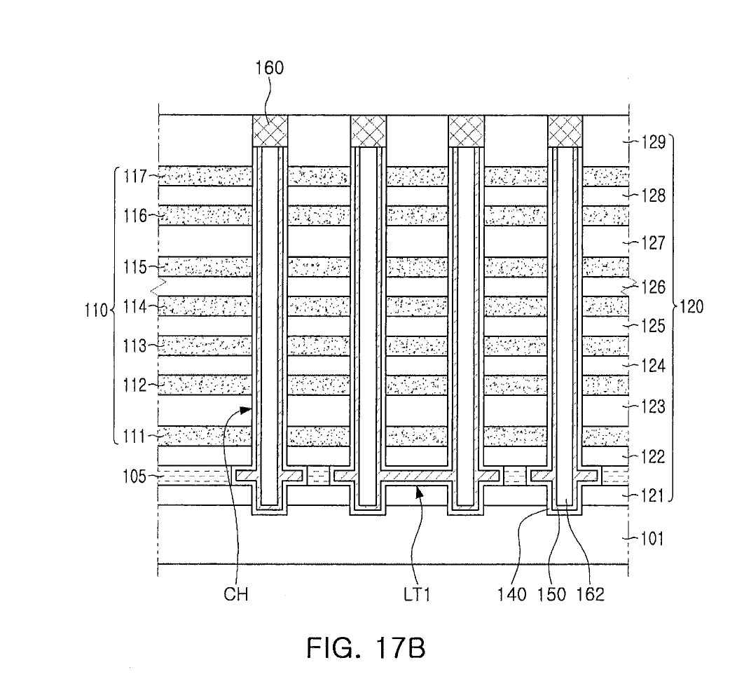

Referring to FIGS. 17A and 17B, gate dielectric layers 140, channel regions 150, first insulating layers 162, and channel pads 160 may be formed in the channel holes CH.

The gate dielectric layers 140 may be formed to have a uniform thickness in an atomic layer deposition (ALD) process or a chemical vapor deposition (CVD) process. In this process, the gate dielectric layers 140 may be fully or partially formed. In other words, portions of the gate dielectric layers 140, extending perpendicularly with respect to the substrate 101 along the channel holes CH, may be formed in the process. The channel regions 150 may be formed on the gate dielectric layers 140 in the channel holes CH.

The gate dielectric layers 140 may also be uniformly formed in the first horizontal tunnels LT1. The channel regions 150 may be formed to fill empty spaces in the first horizontal tunnels LT1. Alternatively, the channel regions 150 may not fill the first horizontal tunnels LT1 but be conformably formed on the gate dielectric layers 140 in the first horizontal tunnels LT1.

The first insulating layers 162 may be formed of an insulating material to fill the channel holes CH. However, in some embodiments, a conductive material, instead of the first insulating layers 162, may fill the spaces between the channel regions 150.

The channel pads 160 may be formed of a conductive material. The channel pads 160 may be electrically connected to the channel regions 150. In a subsequent process, the channel pads 160 may be electrically connected to bit lines BL1 to BLm (refer to FIG. 2) via upper contact plugs or the like.

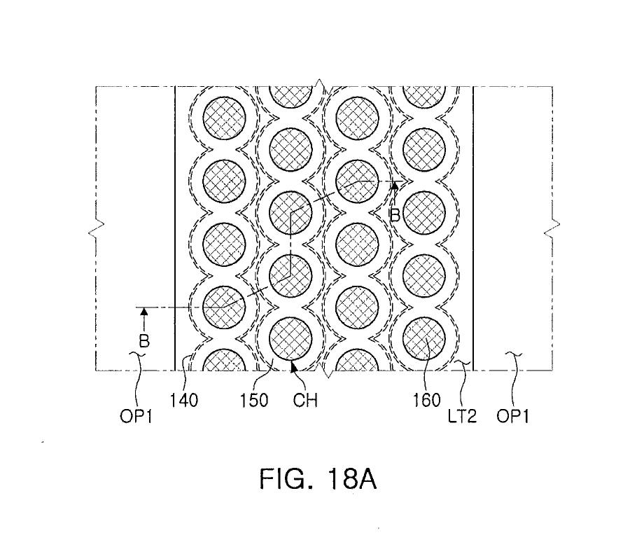

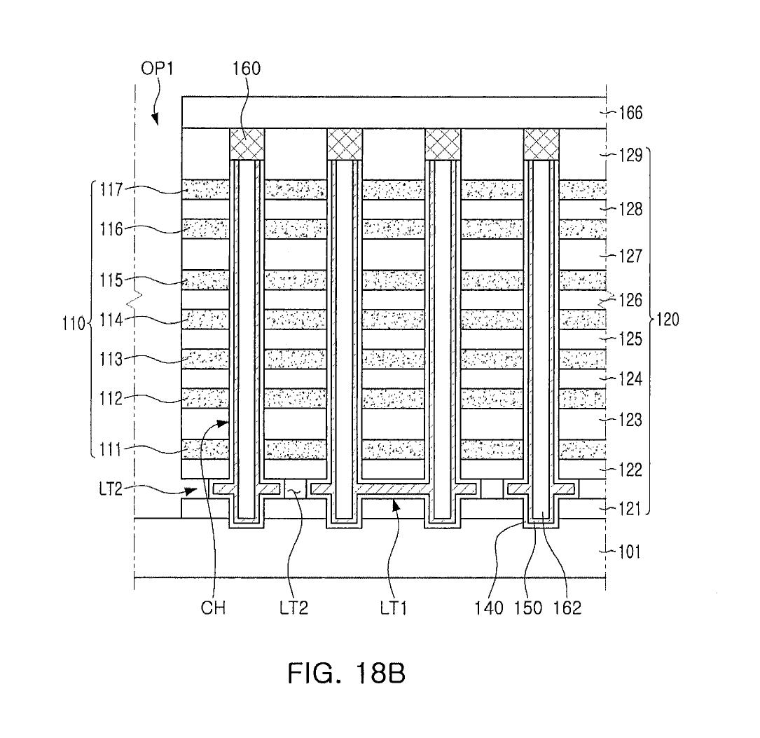

Referring to FIGS. 18A and 18B, a first opening OP1 separating the stacked structure including the first and second sacrificial layers 105 and 110 and the interlayer insulating layers 120 at a predetermined distance may be formed, and the remaining first sacrificial layer 105 exposed through the first opening OP1 may be removed.

Before the first opening OP1 is formed, a second insulating layer 166 may be additionally formed on the uppermost interlayer insulating layer 129 and the channel pads 160 to prevent damage of the channel pads 160 and the channel regions 150 below the channel pads 160.

The first opening OP1 may be formed by providing a mask layer using a photolithography process, and anisotropically etching the stacked structure including the first and second sacrificial layers 105 and 110 and the interlayer insulating layers 120. The first opening OP1 may be formed to have a trench shape extending in one direction, as illustrated in FIG. 18A. The first opening OP1 may expose the substrate 101 between the channel regions 150.

The remaining first sacrificial layer 105 may be selectively removed in an etching process such as a GPE process, and accordingly second horizontal tunnels LT2 may be formed. Sidewalls of the gate dielectric layers 140 may be exposed in the second horizontal tunnels LT2.

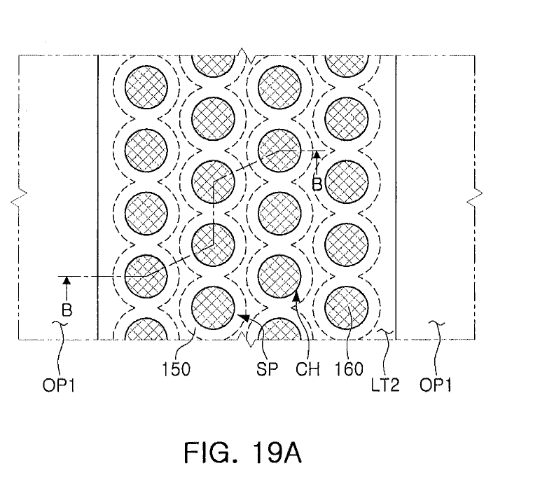

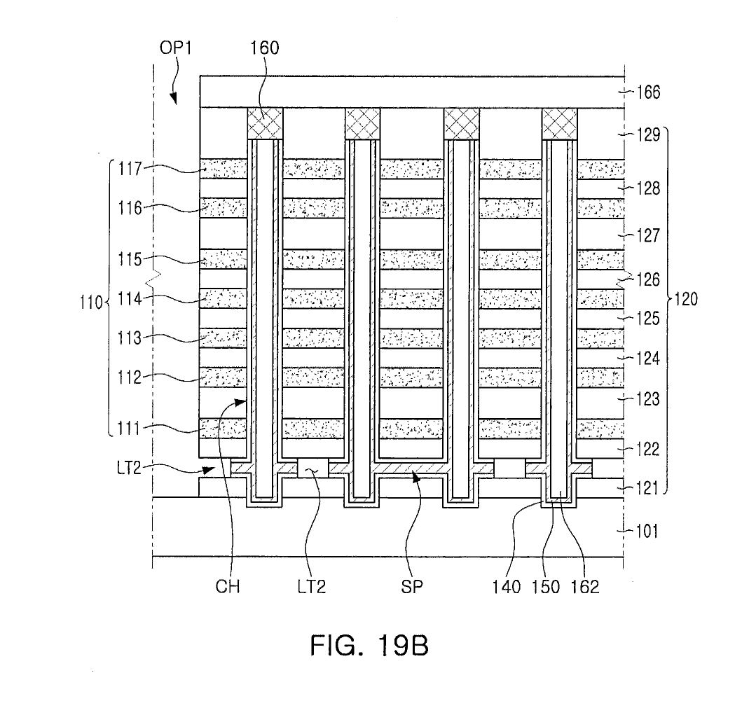

Referring to FIGS. 19A and 19B, the gate dielectric layers 140 exposed in the second horizontal tunnels LT2 may be removed. The gate dielectric layers 140 may be removed by wet etching or dry etching. Thereby, the second horizontal tunnels LT2 may be extended by a thickness of the gate dielectric layers 140.

In this process, the horizontal parts SP including the gate dielectric layers 140 and the channel regions 150 may be finally formed. In this process, the horizontal parts SP may support a stacked structure including the interlayer insulating layers 120 and the second sacrificial layers 110 disposed thereon.

In the process discussed above with reference to FIGS. 16A and 16B, an area of the remaining first sacrificial layer 105 may be inversely proportional to an area of the horizontal parts SP. Accordingly, by appropriately controlling the area of the remaining first sacrificial layer 105 and the area of the horizontal parts SP, the stacked structure including the interlayer insulating layers 120 and the second sacrificial layers 110 disposed thereon may be stably supported in both processes described with reference to FIGS. 16A and 16B, and described with reference to FIGS. 19A and 19B. For example, the stacked structure may be stably supported in this process by the connected horizontal parts SP between the channel regions 150.

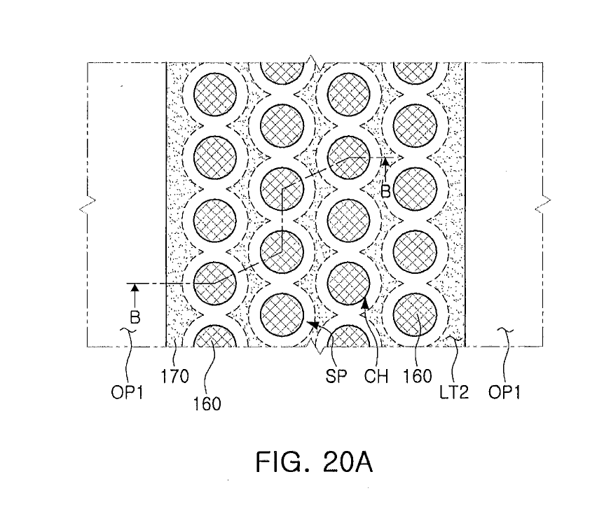

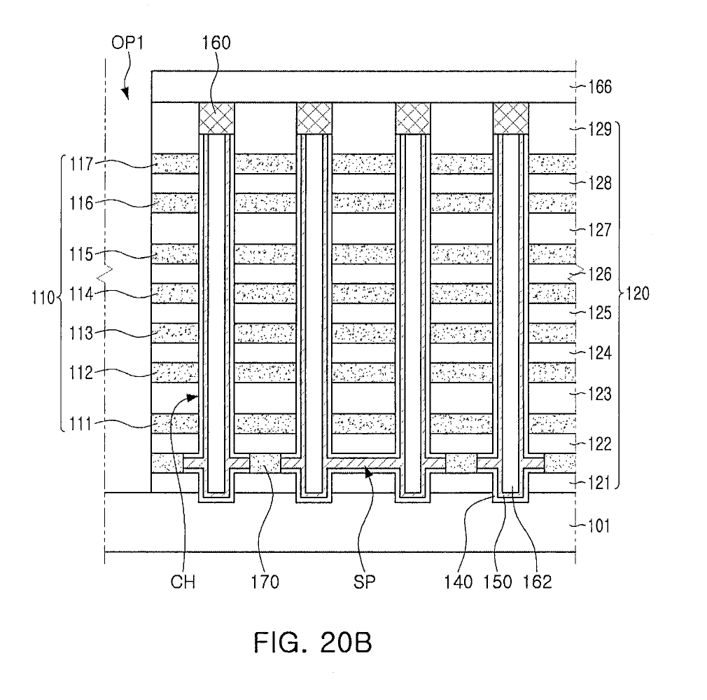

Referring to FIGS. 20A and 20B, horizontal filling layers 170 may be formed in the second horizontal tunnels LT2. The horizontal filling layers 170 may fill empty spaces between the horizontal parts SP, and may form one layer parallel to the upper surface of the substrate 101, together with the horizontal parts SP.

The horizontal filling layers 170 may be, for example, polysilicon, and in these embodiments, may be electrically connected to the channel regions 150. Accordingly, even if the gate dielectric layers 140 are not removed from bottoms of the channel holes CH, the channel regions 150 may be electrically connected to a conductive layer 190 to be formed in a subsequent process and/or the substrate 101, via the horizontal filling layers 170.

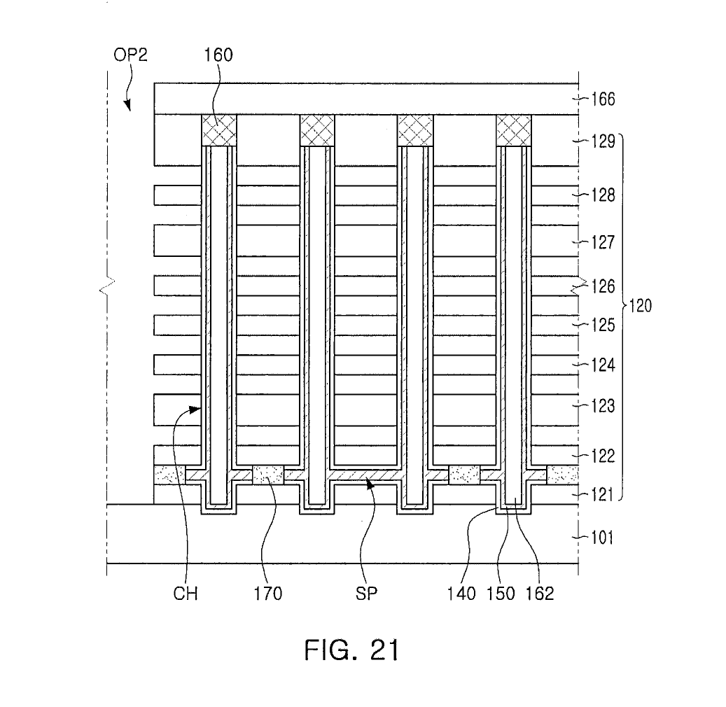

Referring to FIG. 21, a second opening OP2 may be formed, and the second sacrificial layers 110 exposed by the second opening OP2 may be removed. The second opening OP2 may be formed by the same method and at the same position as the first opening OP1.

By forming the second opening OP2, materials of the horizontal filling layers 170 that might have partially formed a sidewall of the stacked structure may be removed. The second sacrificial layers 110 may be selectively removed with respect to the interlayer insulating layers 120 and the horizontal filling layers 170.

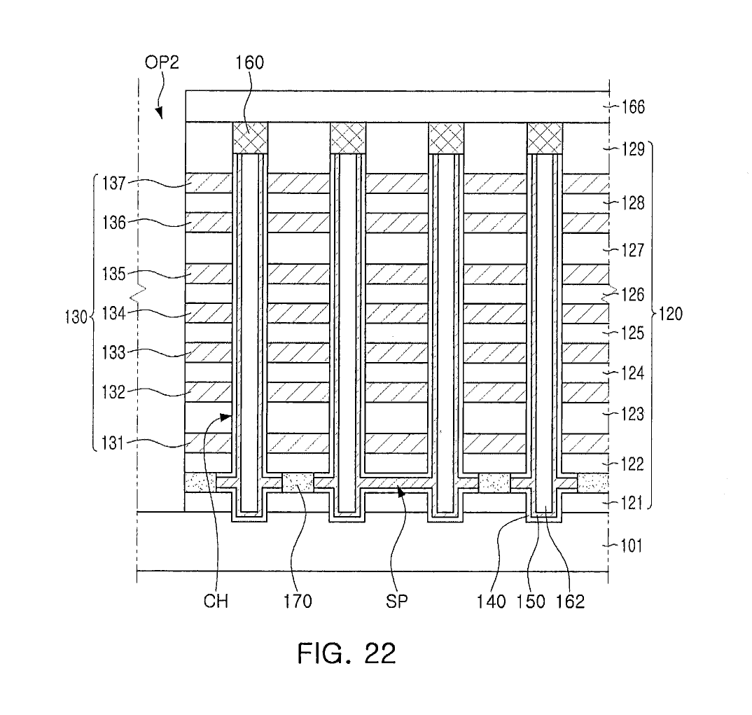

Referring to FIG. 22, gate electrodes 130 may be formed in portions in which the second sacrificial layers 110 have been removed. The gate electrodes 130 may include a metal, polysilicon, or a metal silicide material. The metal silicide material may be, for example, a silicide of a metal selected from cobalt (Co), nickel (Ni), halfnium (Hf), platinum (Pt), tungsten (W), and titanium (Ti), or a combination thereof. When the gate electrodes 130 are formed of the metal silicide material, the gate electrodes 130 may be formed by filling the portions in which the second sacrificial layers 110 have been removed with silicon (Si), forming an additional metal layer thereon, and performing a silicidation process.

After the gate electrodes 130 are formed, a material of the gate electrodes 130 formed in the second opening OP2 may be removed by an additional process. Although not illustrated in the drawings, the gate electrodes 130 may be formed in such a manner that the interlayer insulating layers 120 between the gate electrodes 130 protrude toward the second opening OP2.

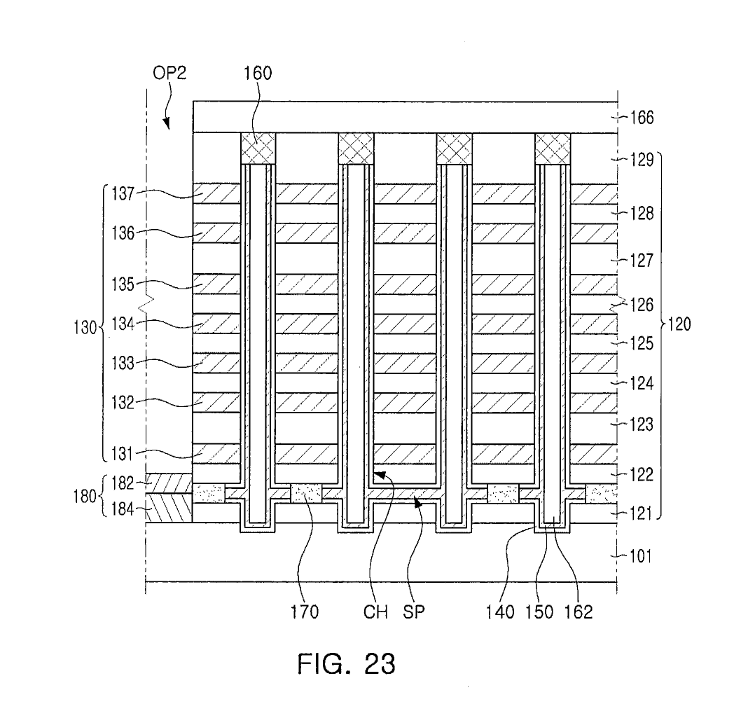

Referring to FIG. 23, a contact line 180 may be formed in the second opening OP2. The contact line 180 may include, for example, first and second impurity areas 182 and 184, by forming polysilicon to a predetermined height and injecting different conductivity-types of impurities into the polysilicon. In some embodiments, the contact line 180 may be formed in a selective epitaxial growth (SEG) process.

Referring also to FIG. 4, a second insulating layer 164 may be formed on a sidewall of the second opening OP2. The second insulating layer 164 may be formed in a spacer shape by forming an insulating material and removing the insulating material from the contact line 180 to expose an upper surface of the contact line 180. In some embodiments, the second insulating layer 164 may be formed in a multilayer.

A conductive layer 190 may be formed in a portion defined by the second insulating layer 164. Before the conductive layer 190 is formed, a diffusion barrier layer may further be formed on the second insulating layer 164. The diffusion barrier layer may include a nitride, such as TiN or WN.

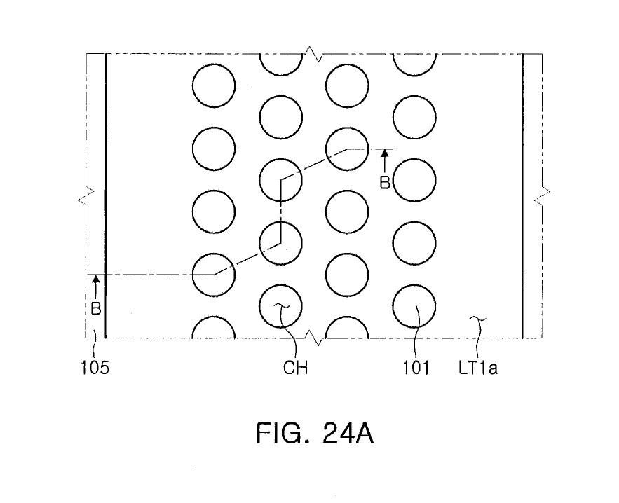

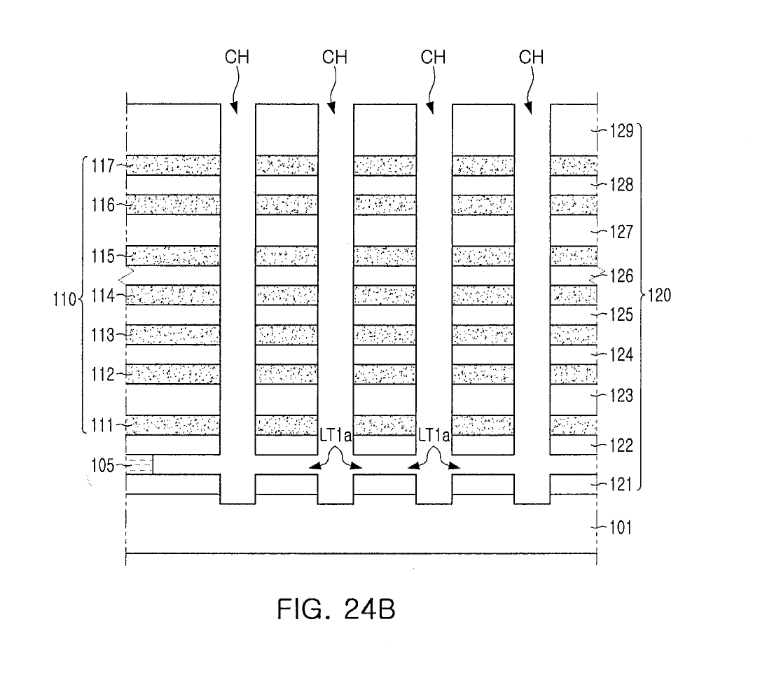

FIGS. 24A to 28B are process views illustrating processing steps in the fabrication of a semiconductor device according to some embodiments of the present inventive concept. In FIGS. 24A to 28B, a method of fabricating the semiconductor device 100c illustrated in FIGS. 9 and 10 may be described, and regions corresponding to those illustrated in FIGS. 9 and 10 may be illustrated. Hereinafter, descriptions duplicated from those described with reference to FIGS. 14A to 23 will be omitted in the interest of brevity.

First, as discussed above with respect to FIGS. 14A to 15B, a stacked structure including the first and second sacrificial layers 105 and 110 and the interlayer insulating layers 120 may be formed, and channel holes CH may be formed.

Referring to FIGS. 24A and 24B, first horizontal tunnels LT1a may be formed by partially removing the first sacrificial layer 105 through the channel holes CH.

In particular, the first horizontal tunnels LT1a in some embodiments may be formed to extend into an area at which a first opening OP1 is to be formed in a subsequent process. By forming the first horizontal tunnels LT1a in this process, a stacked structure of the interlayer insulating layers 120 and the second sacrificial layers 110 disposed on the first horizontal tunnels LT1a may be supported by the remaining first sacrificial layer 105.

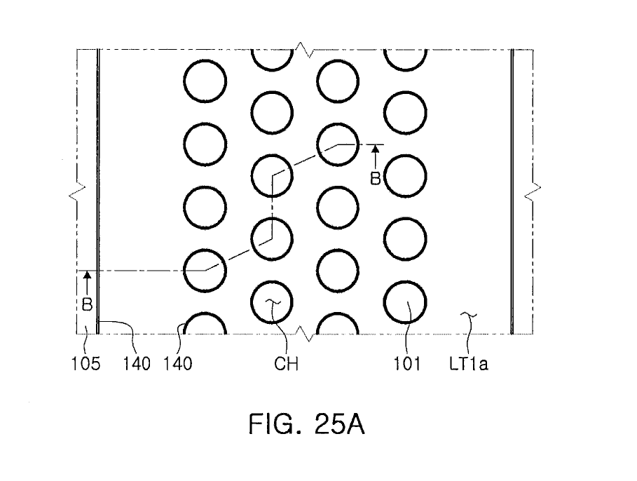

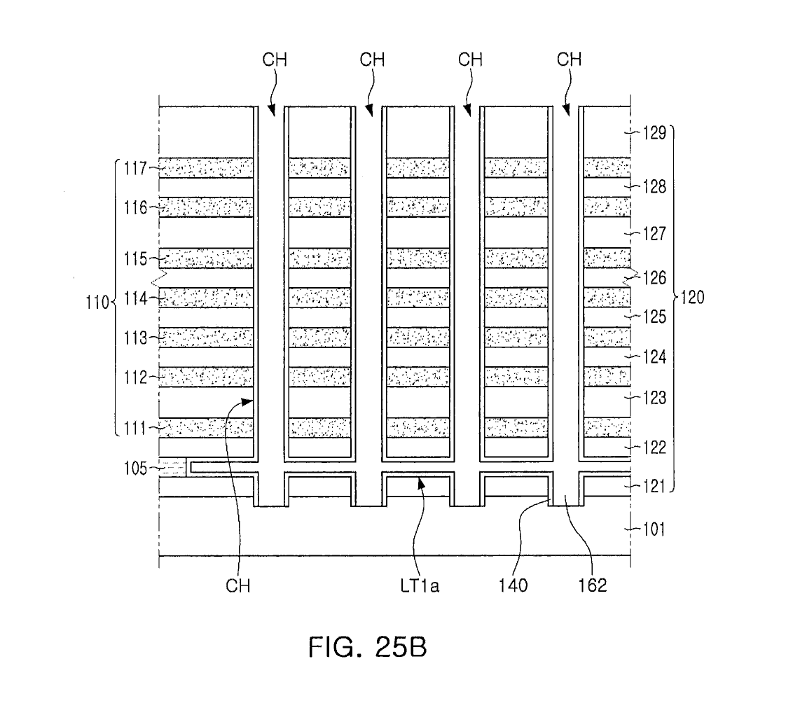

Referring to FIGS. 25A and 25B, gate dielectric layers 140 may be formed in the channel holes CH, and gate dielectric layers 140 may be partially removed from bottoms of the channel holes CH.

The gate dielectric layers 140 may also be uniformly formed in the first horizontal tunnels LT1a. By removing the gate dielectric layers 140 formed at the bottoms of the channel holes CH by using an etching process after forming the gate dielectric layers 140, the substrate 101 may be exposed on the bottoms of the channel holes CH.

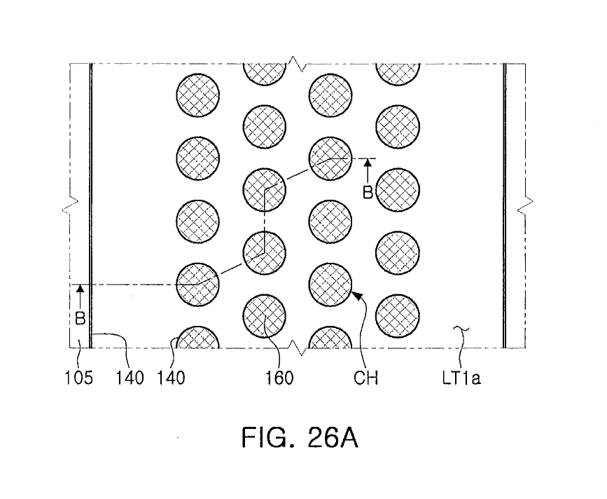

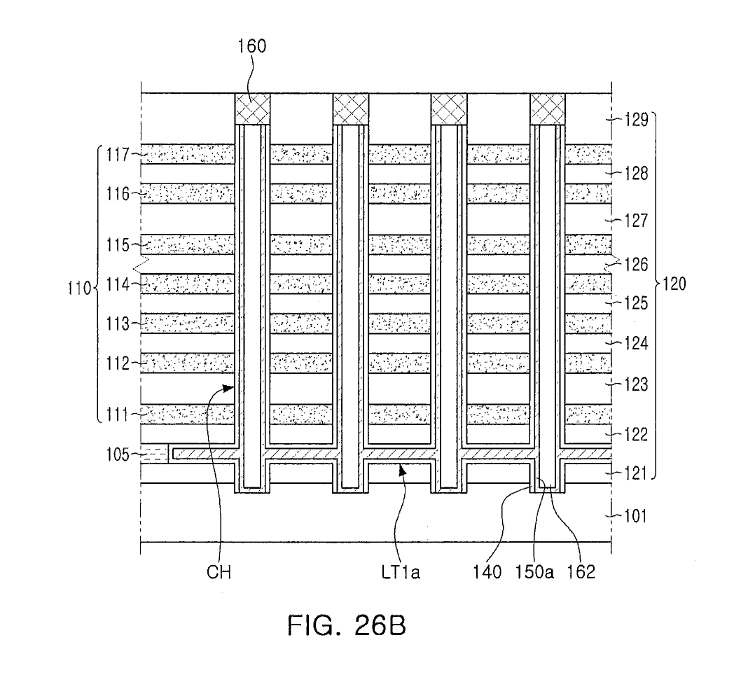

Referring to FIGS. 26A and 26B, channel regions 150a, first insulating layers 162, and channel pads 160 may be formed in the channel holes CH.

The channel regions 150a may be formed on the gate dielectric layers 140 along the channel holes CH, and may fill empty spaces of the first horizontal tunnels LT1a. Alternatively, the channel regions 150a may not fill the first horizontal tunnels LT1a but be conformably formed on the gate dielectric layers 140 in the first horizontal tunnels LT1a, like those in some embodiments described with reference to FIG. 6A. In these embodiments, the empty spaces of the first horizontal tunnels LT1a may be filled with the first insulating layers 162.

In this process, since the substrate 101 is exposed on the bottoms of the channel holes CH, the channel regions 150a may be in direct contact with the substrate 101 on the bottoms of the channel holes CH.

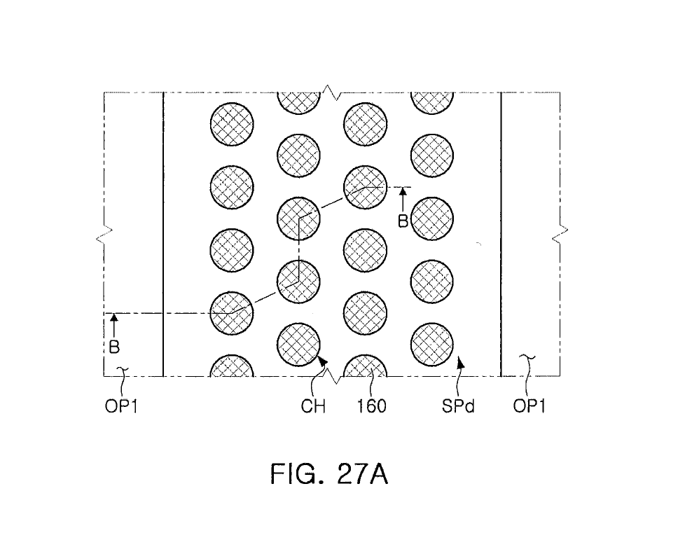

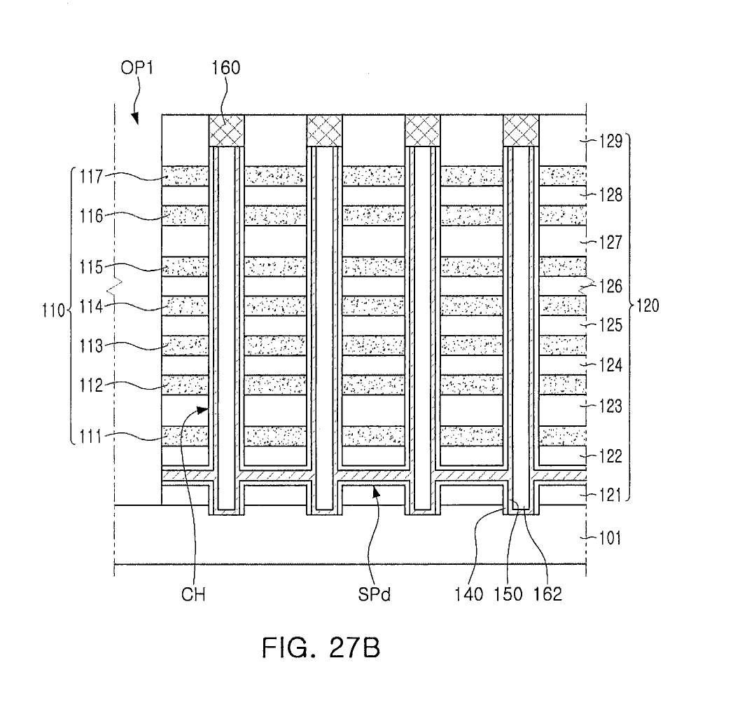

Referring to FIGS. 27A and 27B, a first opening OP1 may be formed, and the gate dielectric layers 140 and the first sacrificial layer 105 remaining at ends of the first horizontal tunnels LT1a may be removed.

The first opening OP1 may be formed at an area including the gate dielectric layers 140 formed at both ends of the first horizontal tunnels LT1a. Accordingly, by forming the first opening OP1, the gate dielectric layers 140 formed at both ends of the first horizontal tunnels LT1a may be removed.

In this process, horizontal parts SPd may be formed in the first horizontal tunnels LT1a. In some embodiments, the horizontal filling layers 170 illustrated in FIG. 4 may not be additionally formed.

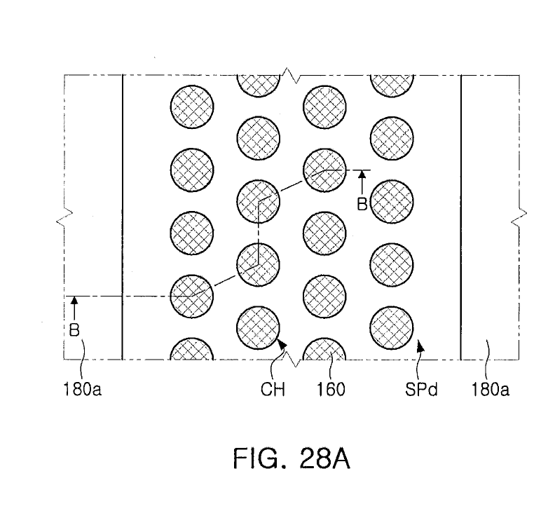

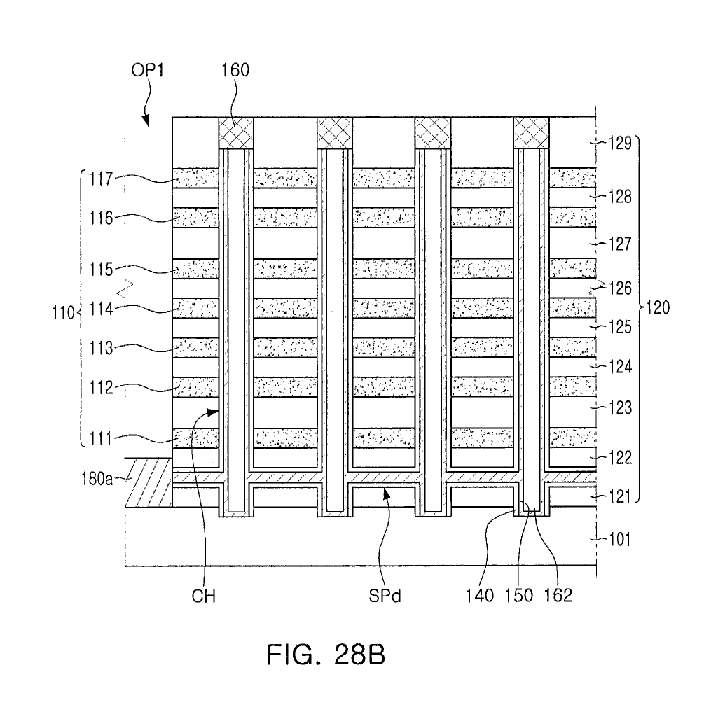

Referring to FIGS. 28A and 28B, contact lines 180a may be formed below the first opening OP1. The contact lines 180a may be formed of, for example, polysilicon including impurities.

As discussed with reference to FIGS. 21 and 22, the second sacrificial layers 110 may be removed, and gate electrodes 130 may be formed.

Referring also to FIG. 10, a second insulating layer 164 may be formed, and a conductive layer 190 may be formed in an area defined by the second insulating layer 164.

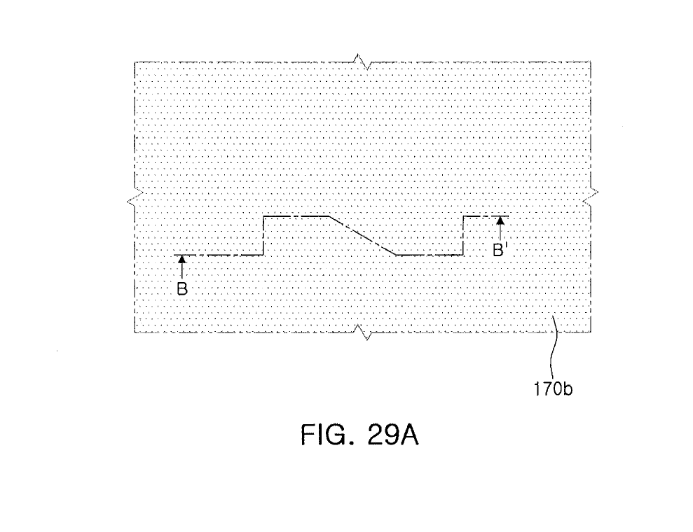

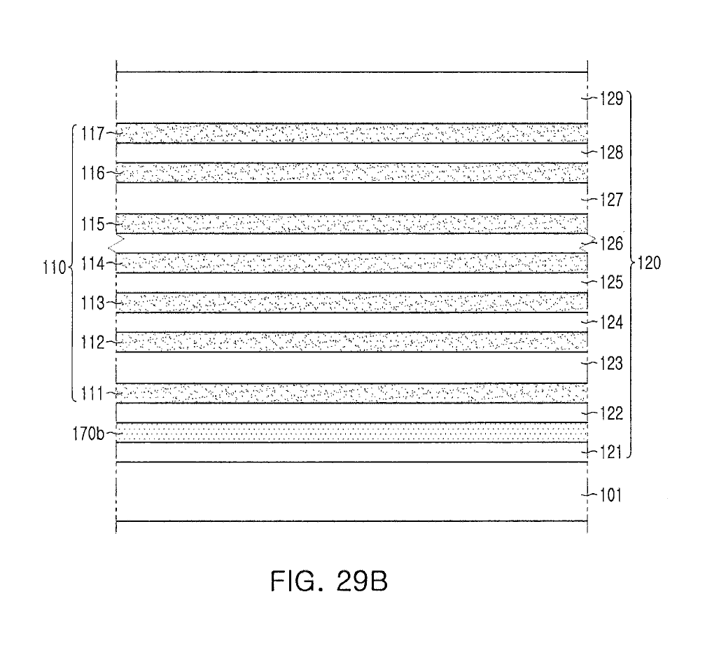

FIGS. 29A to 34B are process views illustrating processing steps in the fabrication of a semiconductor device according to some embodiments of the present inventive concept. In FIGS. 29A to 34B, a method of fabricating the semiconductor device 100d illustrated in FIGS. 11 and 12 may be described, and regions corresponding to those illustrated in FIGS. 11 and 12 may be illustrated.

Referring to FIGS. 29A and 29B, a horizontal filling layer 170b, sacrificial layers 110, and interlayer insulating layers 120 may be alternately formed on a substrate 101. In a subsequent process, the sacrificial layers 110 may be replaced by the gate electrodes 130.

In some embodiments, the first sacrificial layer 105 illustrated in FIGS. 14A and 14B may not be formed, and the horizontal filling layer 170b may be formed together with the sacrificial layers 110. The horizontal filling layer 170b may be, for example, an insulating material such as silicon oxide, however, it will be understood that embodiments of the present inventive concept are not limited thereto.

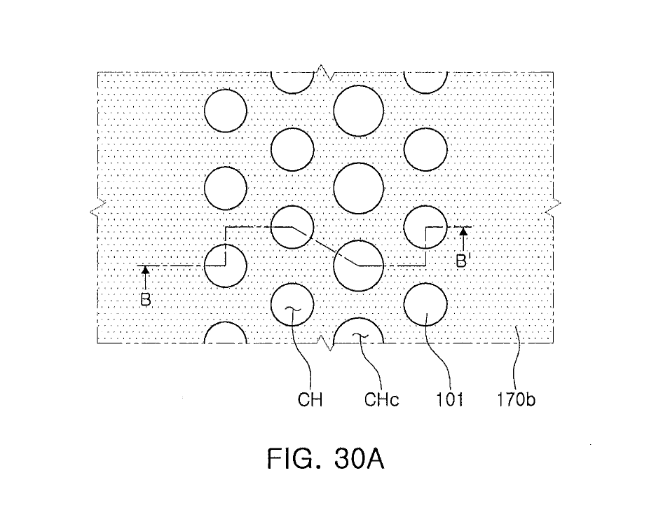

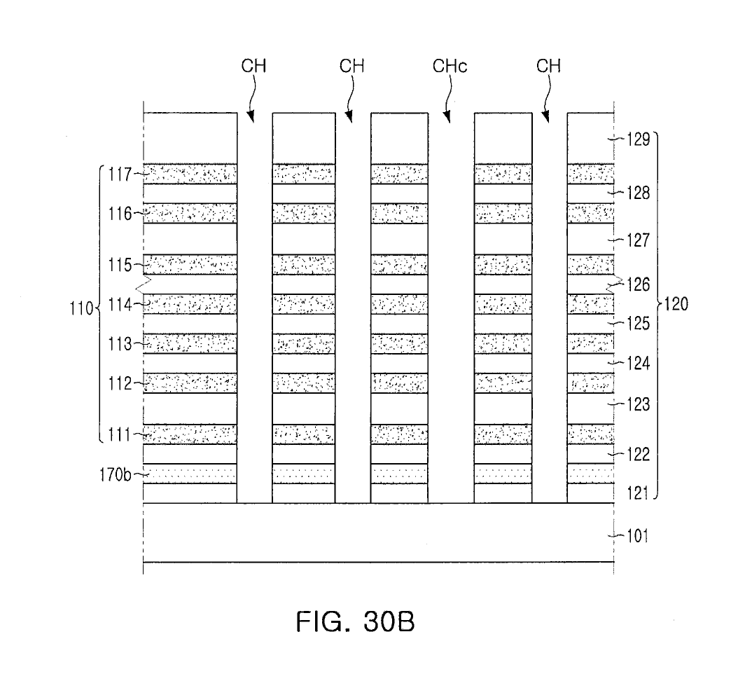

Referring to FIGS. 30A and 30B, channel holes CH and CHc perpendicularly extending to the substrate 101 may be formed. The channel holes CH and CHc may be formed by anisotropically etching the horizontal filling layer 170b, the sacrificial layers 110, and the interlayer insulating layers 120. In some embodiments, the substrate 101 may be partially recessed by the channel holes CH and CHc.

In some embodiments of the present inventive concept, the channel holes CHc may have a relatively large size.

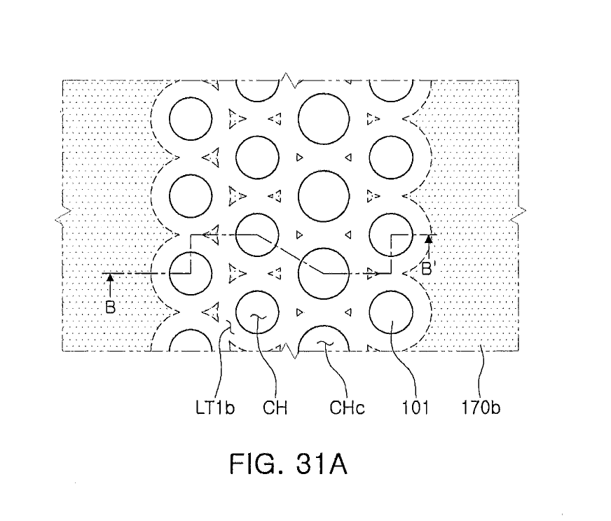

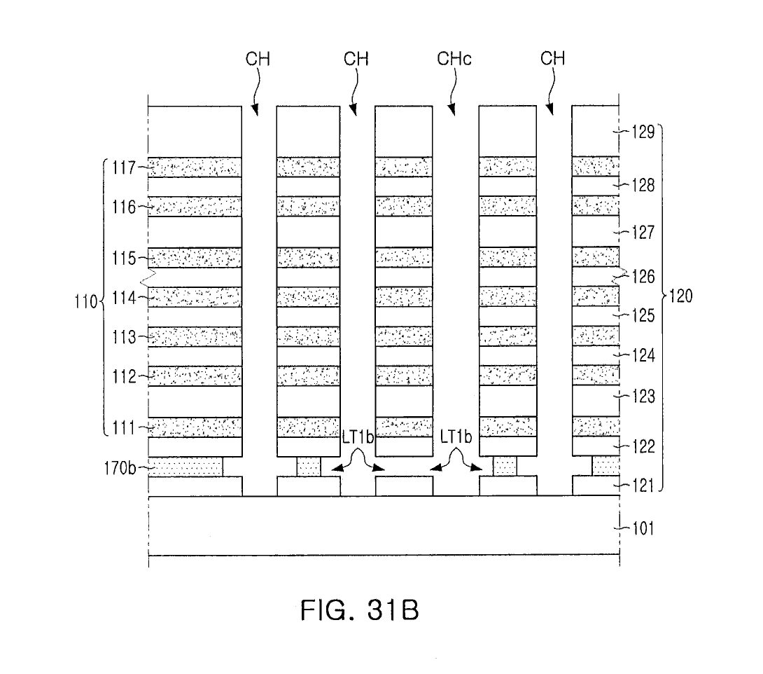

Referring to FIGS. 31A and 31B, first horizontal tunnels LT1b may be formed by partially removing the horizontal filling layer 170b through the channel holes CH and CHc.

The first horizontal tunnels LT1b may be formed in a circular shape surrounding the channel holes CH and CHc and connected to each other. Accordingly, the horizontal filling layer 170b may remain isolated between the channel holes CH and CHc.

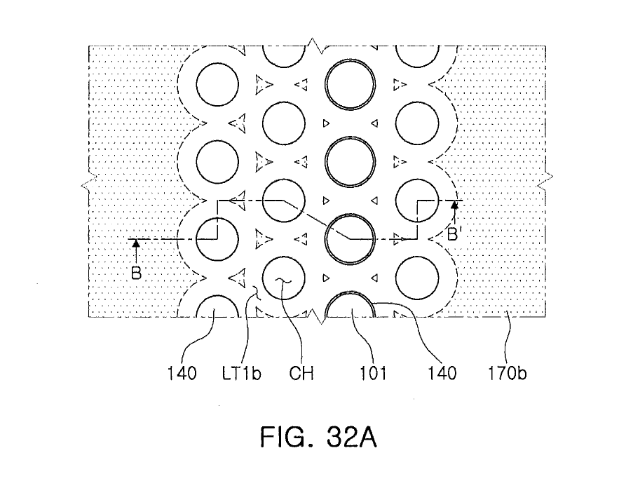

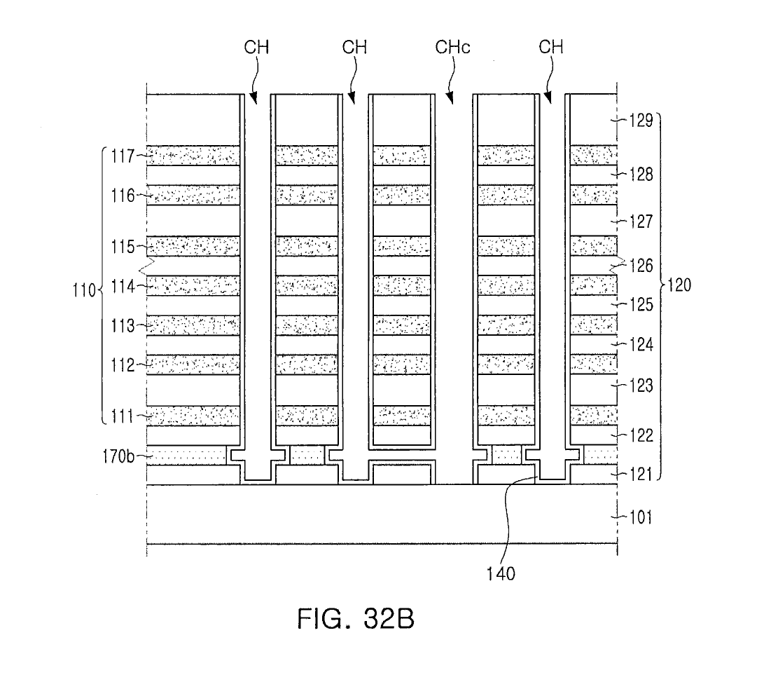

Referring to FIGS. 32A and 32B, gate dielectric layers 140 may be formed in the channel holes CH and CHc, and the gate dielectric layers 140 may be partially removed from bottoms of the channel holes CHc.

The gate dielectric layers 140 may also be uniformly formed in the first horizontal tunnels LT1b.

Since the gate dielectric layers 140 are partially removed at the bottoms of the channel holes CHc having a relatively large size by an etching process, the substrate 101 may be exposed at the bottoms of the channel holes CHc. Such a structure may be formed by using characteristics of the etching process in which an etchant such as an etching gas easily penetrates only into the channel holes CHc having the relatively large size and thereby the gate dielectric layers 140 formed at the bottoms of the channel holes CHc having the relatively large size are removed. However, in some embodiments, at least portions of the gate dielectric layers 140 formed at bottoms of the channel holes CH having a relatively small size may be removed.

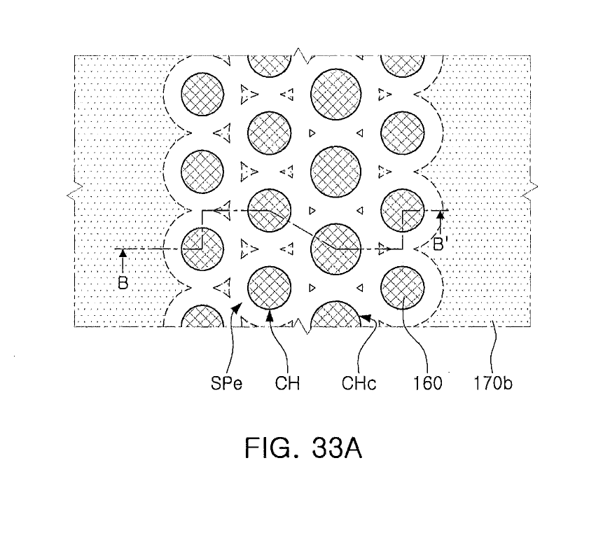

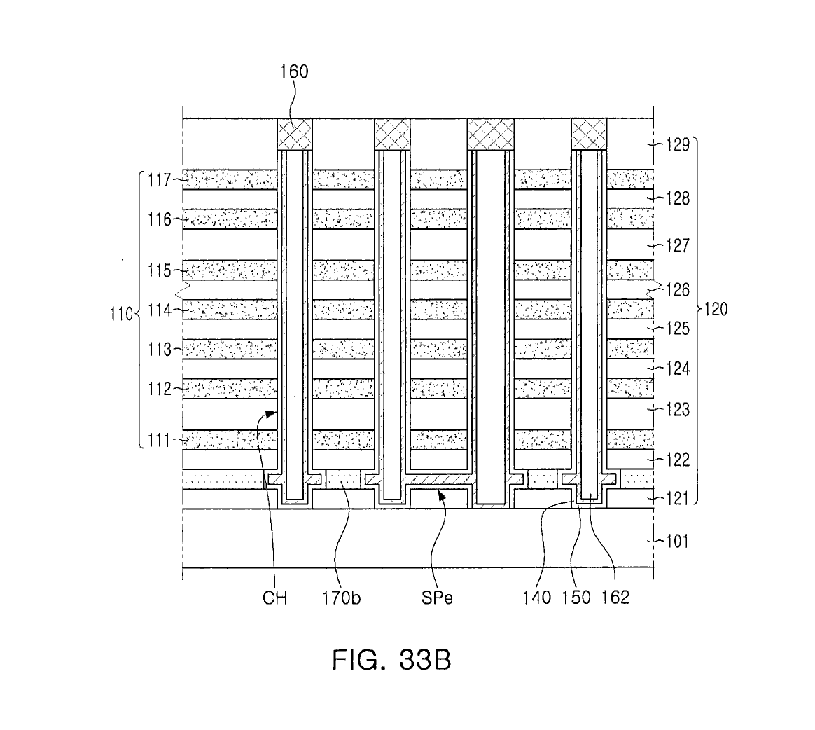

Referring to FIGS. 33A and 33B, channel regions 150, first insulating layers 162, and channel pads 160 may be formed in the channel holes CH and CHc. In this process, the channel regions 150 may be formed in the first horizontal tunnels LT1b to form horizontal parts SPe.

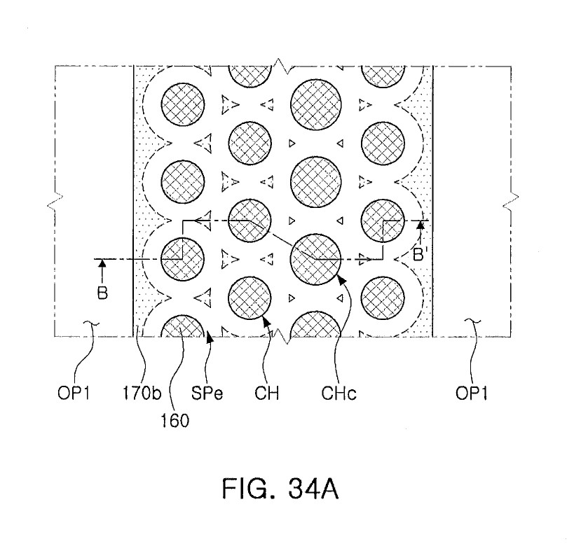

Referring to FIGS. 34A and 34B, a first opening OP1 may be formed, the sacrificial layers 110 exposed through the first opening OP1 may be removed, and gate electrodes 130 may be formed in areas in which the sacrificial layers 110 are removed.

Referring also to FIG. 12, an impurity area 103 may be formed to a predetermined depth by injecting impurities in the substrate 101 exposed to the first opening OP1. A conductive layer 190a may be formed on the impurity area 103.

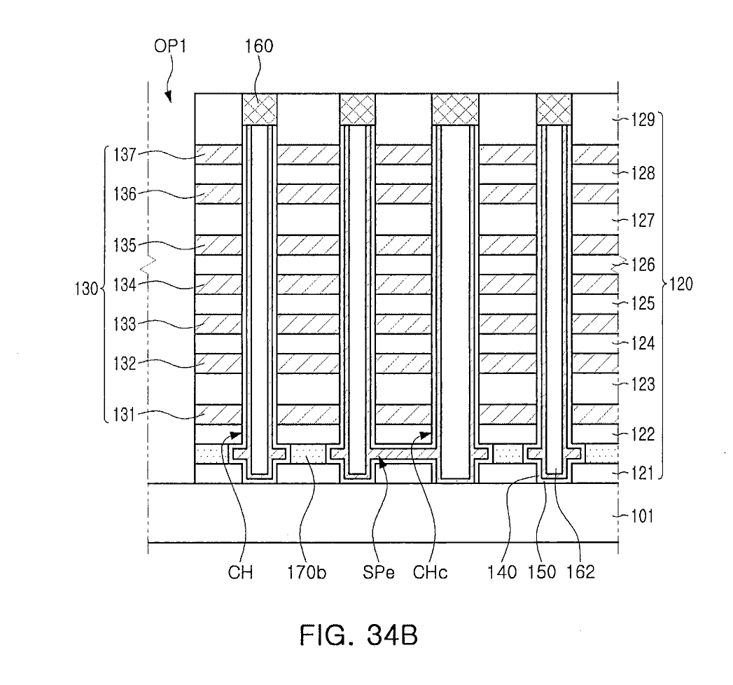

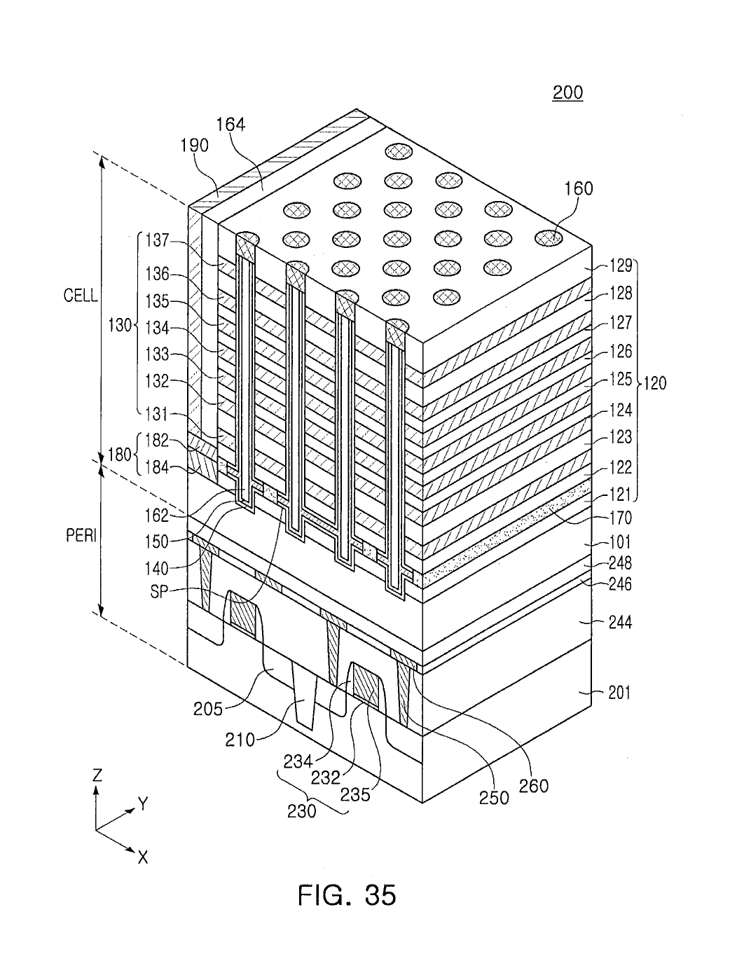

FIG. 35 is a perspective view schematically illustrating a semiconductor device according to some embodiments of the present inventive concept. Referring to FIG. 35, a semiconductor device 200 may include a cell region CELL and a peripheral circuit region PERI.

The cell region CELL may correspond to a region in which the memory cell array 20 of FIG. 1 is disposed, and the peripheral circuit region PERI may correspond to a region in which a driving circuit of the memory cell array 20 of FIG. 1 is disposed. The cell region CELL may be disposed on the peripheral circuit region PERI. In some embodiments, the cell region CELL may disposed below the peripheral circuit region PERI.

The cell region CELL may include a substrate 101, a plurality of channel regions 150 disposed perpendicular to an upper surface of the substrate 101, horizontal parts SP disposed to be connected to the channel regions 150 on the substrate 101, horizontal filling layers 170 disposed at outwardly of the horizontal parts SP, and a plurality of interlayer insulating layers 120 and a plurality of gate electrodes 130 formed on outer sidewalls of the channel regions 150. The cell region CELL may further include gate dielectric layers 140, channel pads 160, a contact line 180, and a conductive layer 190.

In some embodiments, the cell region CELL is illustrated to have the same structure as those in some embodiments illustrated in FIGS. 3 and 4, however, it will be understood that embodiments of the present inventive concept is not limited thereto. The cell region CELL may include, for example, various semiconductor devices according to various embodiments of the present inventive concept, described with reference to FIGS. 6A to 13B.

The peripheral circuit region PERI may include a base substrate 201, circuit devices 230 arranged on the base substrate 201, contact plugs 250, and interconnection lines 260.

The base substrate 201 may have an upper surface extending in an x-axis direction and a y-axis direction. The base substrate 201 may include a device isolation layer 210 and an active region defined by the device isolation layer 210. Doped areas 205 including impurities may be formed in portions of the active region. The base substrate 201 may include a semiconductor material such as a Group IV semiconductor, a Group III-V semiconductor compound, or a Group II-VI semiconductor.

The circuit devices 230 may include planar transistors. Each of the circuit devices 230 may include a circuit gate insulating layer 232, a spacer 234, and a circuit gate electrode 235. Doped areas 205 may be formed in the base substrate 201 disposed at both sides of the circuit gate electrodes 235, and may function as source areas or drain areas of the circuit devices 230.

A plurality of peripheral insulating layers 244, 246, and 248 may be formed on the circuit devices 230 on the base substrate 201. The contact plugs 250 may be connected to the doped areas 205 through the peripheral insulating layers 244. Electrical signals may be applied to the circuit devices 230 through the contact plugs 250. The contact plugs 250 may be connected to the circuit gate electrodes 235 in an area that is not illustrated in FIG. 35. The interconnection lines 260 may be connected to the contact plugs 250. In some embodiments, the interconnection lines 260 may be formed in a plurality of layers.

After the peripheral circuit region PERI is formed, the substrate 101 of the cell region CELL may be formed thereon to form the cell region CELL. A size of the substrate 101 may be the same as or a smaller than the base substrate 201. The substrate 101 may be formed of polysilicon. Alternatively, the substrate 101 may be formed of amorphous silicon, and then crystallized.

The cell region CELL and the peripheral circuit region PERI may be connected in an area that is not illustrated in FIG. 35. For example, end portions of the gate electrodes 130 in the y-axis direction may be electrically connected to the circuit devices 230.

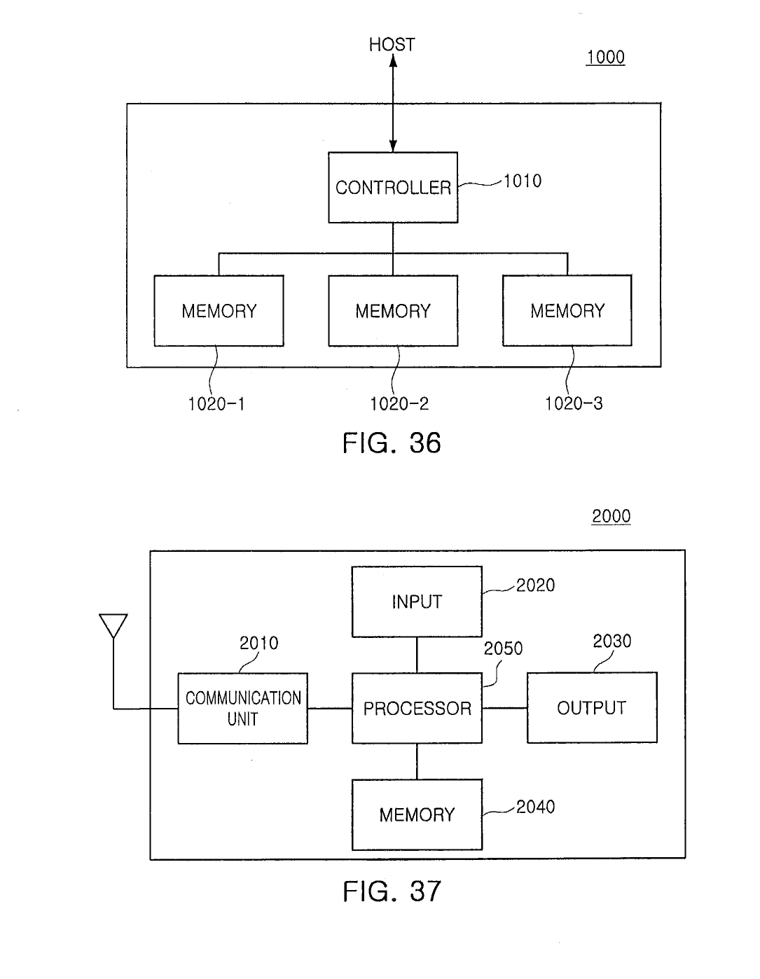

FIG. 36 is a block diagram illustrating a storage apparatus including a semiconductor device according to some embodiments of the present inventive concept. Referring to FIG. 36, a storage apparatus 1000 according to some embodiments may include a controller 1010 communicating with a host HOST, and memories 1020-1, 1020-2, and 1020-3 storing data. Each of the memories 1020-1, 1020-2, and 1020-3 may include the semiconductor devices according to the various embodiments of the present inventive concept discussed above with reference to FIGS. 3 and 13B.

The host HOST communicating with the controller 1010 may be a variety of electronic devices in which the storage apparatus 1000 is installed, such as a smartphone, a digital camera, a desktop PC, a laptop computer, or a media player. The controller 1010 may receive a request for data reading or writing from the host HOST to generate a command CMD for writing data to the memories 1020-1, 1020-2, and 1020-3 or reading data from the memories 1020-1, 1020-2, and 1020-3.

As illustrated in FIG. 36, one or more memories 1020-1, 1020-2, and 1020-3 may be connected in parallel to the controller 1010 in the storage apparatus 1000. By connecting the plurality of memories 1020-1, 1020-2, and 1020-3 to the controller 1010 in parallel, the storage device 1000 having a large amount of capacity, such as a solid state drive (SSD), may be implemented.

FIG. 37 is a block diagram illustrating an electronic device including a semiconductor device according to some embodiments of the present inventive concept.

Referring to FIG. 37, an electronic device 2000 according to some embodiments may include a communication unit 2010, an input 2020, an output 2030, a memory 2040, and a processor 2050.

The communication unit 2010 may include a wired/wireless communications module, such as a wireless internet module, a short-range communications module, a GPS module, or a mobile communications module. The wired/wireless communications module included in the communication unit 2010 may be connected to an external communications network by a variety of communications standards in order to transmit and receive data.

The input 2020 is a module supplied to a user to control operations of the electronic device 2000, and may include a mechanical switch, a touchscreen, a voice recognition module, or the like. Furthermore, the input 2020 may include a trackball, a laser pointer mouse, or a finger mouse, and may further include a variety of sensor modules in which a user can input data.

The output 2030 may output information processed by the electronic device 2000 in audio or video form. The memory 2040 may store a program for processing or controlling the processor 2050, data, or the like. The processor 2050 may write data or read data by transmitting a command to the memory 2040 according to a required operation.

The memory 2040 may be embedded in the electronic device 2000 or may communicate with the processor 2050 via a separate interface. When the memory 2040 communicates with the processor 2050 via the separate interface, the processor 2050 may write data to, or read data from, the memory 2040 using a variety of interface standards, such as SD, SDHC, SDXC, MICRO SD, or USB.

The processor 2050 may control operations of each unit included in the electronic device 2000. The processor 2050 may perform controlling or processing operations related to voice calls, video calls, or data communication, or may control or process operations for multimedia playback and management. Furthermore, the processor 2050 may process an input transmitted via the input 2020 from a user, and then output a result thereof via the output 2030. Further, the processor 2050 may write data required to control operations of the electronic device 2000 to the memory 2040, or read data from the memory 2040, as discussed above. At least one of the processor 2050 and the memory 2040 may include the semiconductor devices according to the various embodiments of the present inventive concept discussed above with reference to FIGS. 3 and 13B.

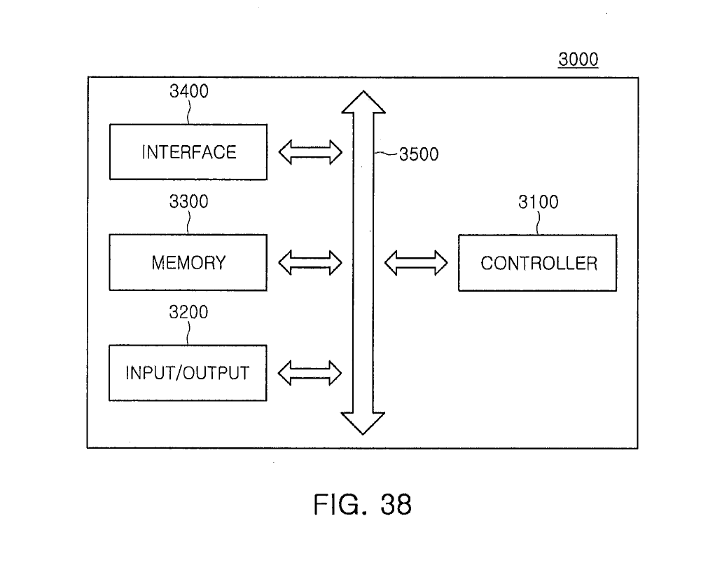

FIG. 38 is a schematic diagram illustrating a system including a semiconductor device according to some embodiments of the present inventive concept. Referring to FIG. 38, a system 3000 may include a controller 3100, an input/output 3200, a memory 3300, and an interface 3400. The system 3000 may be a mobile system or an information transmitting or receiving system. The mobile system may be a PDA, a portable computer, a web tablet, a wireless phone, a mobile phone, a digital music player, or a memory card.

The controller 3100 may function to execute a program or control the system 3000. The controller 3100 may be, for example, a microprocessor, a digital signal processor, a microcontroller, or the like.

The input/output 3200 may be used to input data to the system 3000 or output data from the system 3000. The system 3000 may be connected to an external device, such as a PC or a network, through the input/output 3200 to exchange data with the external device. The input/output 3200 may be, for example, a keypad, a keyboard, or a display.

The memory 3300 may store code and/or data for operating the controller 3100, and/or data processed in the controller 3100. The memory 3300 may include a semiconductor device according to one of some embodiments of the present inventive concept.

The interface 3400 may be a data transmission path between the system 3000 and an external device. The controller 3100, the input/output 3200, the memory 3300, and the interface 3400 may communicate through a bus 3500.

At least one of the controller 3100 and the memory 3300 may include the semiconductor devices according to the various embodiments of the present inventive concept, discussed above with reference to FIGS. 3 and 13B.

As set forth above, according to some embodiments of the present inventive concept, a semiconductor device having improved reliability may be provided by forming a horizontal part connected between channel holes below a stacked structure of gate electrodes.

While example embodiments have been shown and discussed above, it will be apparent to those skilled in the art that modifications and variations could be made without departing from the scope of the inventive concept as defined by the appended claims.

What is claimed is:

1. A semiconductor device, comprising:
a stacked structure including gate electrodes and interlayer insulating layers alternately stacked on a substrate;
channel holes extending perpendicular to the substrate through the stacked structure and including channel regions therein; and
horizontal parts at lower portions of the stacked structure and including areas in which the channel regions are horizontally elongated from the channel holes,
wherein the horizontal parts surround respective channel holes, and are connected to each other between at least a portion of the channel holes.

2. The semiconductor device of claim 1, wherein the horizontal parts are connected to each other between the channel holes in parallel in one direction.

3. The semiconductor device of claim 1:
wherein the horizontal parts include circular portions surrounding respective channel holes; and
wherein some circular portions are connected to each other.

4. The semiconductor device of claim 1, further comprising a horizontal filling layer alongside the horizontal parts and filling a space between the horizontal parts.

5. The semiconductor device of claim 4, wherein the horizontal filling layer includes an isolated portion surrounded by the horizontal parts.

6. The semiconductor device of claim 1, further comprising gate dielectric layers extending perpendicular to the substrate along the channel regions and between the channel regions and the gate electrodes,
wherein the horizontal parts include portions formed by horizontally elongated gate dielectric layers.

7. The semiconductor device of claim 6, wherein the gate dielectric layers in the horizontal parts are on upper and lower surfaces of the channel regions and do not cover side surfaces of the channel regions.

8. The semiconductor device of claim 6, wherein the lower surfaces of the channel regions are isolated from the substrate by the gate dielectric layers.

9. The semiconductor device of claim 1, wherein the horizontal parts include at least two layers spaced apart from each other in a direction perpendicular to the upper surface of the substrate.

10. The semiconductor device of claim 1, further comprising a lower interlayer insulating layer between the horizontal parts and the substrate.

11. The semiconductor device of claim 1, wherein the channel holes extend through the horizontal parts and recess portions of the substrate.

12. The semiconductor device of claim 1, further comprising contact lines between the channel holes at predetermined intervals, and connected to at least one of the horizontal parts and the substrate.

13. The semiconductor device of claim 12, wherein the contact lines are electrically connected to the horizontal parts.

14. The semiconductor device of claim 13, wherein the contact lines include a first impurity area and a second impurity area, arranged in a vertical direction and respectively including different conductivity-type impurities.

15. A semiconductor device, comprising:
a stacked structure including gate electrodes and interlayer insulating layers alternately stacked on a semiconductor substrate;
channel holes extending perpendicular to the semiconductor substrate and through the stacked structure;
horizontal parts between the semiconductor substrate and the stacked structure, surrounding respective channel holes and connected to each other between at least a portion of the channel holes; and
a horizontal filling layer disposed alongside the horizontal parts and filling a space between the horizontal parts.

16. A semiconductor device, comprising:
a semiconductor substrate;
a stacked structure including gate electrodes on the semiconductor substrate;
a supporting structure between the semiconductor substrate and the stacked structure; and
channel holes extending perpendicular to the semiconductor substrate and through the stacked structure and the supporting structure,
wherein the semiconductor substrate and the stacked structure are connected through at least portions of the channel holes.

17. The semiconductor device of claim 16:
wherein the stacked structure further includes interlayer insulating layers alternatively stacked with the gate electrodes; and
wherein the channel holes extend through both the gate electrodes and the interlayer insulating layers.

18. The semiconductor device of claim 17, further comprising a common source line connected to the stacked structure and the semiconductor substrate.

19. The semiconductor device of claim 18, wherein the interlayer insulating layers are not removed from bottom surfaces of the channel holes due to presence of the supporting structure.

20. The semiconductor device of claim 17:
wherein the channel holes included channel regions therein; and
wherein the supporting structure comprises:
horizontal parts at lower portions of the stacked structure and including areas in which the channel regions are horizontally elongated from the channel holes, the horizontal parts surrounding respective channel holes and being connected to each other between at least a portion of the channel holes.
